(19) United States
(12) Patent Application Publication
(10) Pub. No.: US 2019/0155147 A1
(43) Pub. Date: May 23, 2019

(54) PHOTOMASK, METHOD FOR PRODUCING PHOTOMASK, AND METHOD FOR PRODUCING COLOR FILTER USING PHOTOMASK

(71) Applicant: TOPPAN PRINTING CO., LTD., Tokyo (JP)

(72) Inventors: Akihito OKUMURA, Tokyo (JP); Hiroaki MIYAJI, Tokyo (JP); Takehiro YAMADA, Tokyo (JP)

(73) Assignee: TOPPAN PRINTING CO., LTD., Tokyo (JP)

(21) Appl. No.: 16/252,632

(22) Filed: Jan. 19, 2019

Related U.S. Application Data
(63) Continuation of application No. PCT/JP2017/025967, filed on Jul. 18, 2017.

(30) Foreign Application Priority Data
Jul. 21, 2016 (JP) 2016-143333
Dec. 9, 2016 (JP) 2016-238997

(51) Int. Cl. G03F 1/70; G02F 1/1335; G03F 7/20; G03F 7/00; G03F 1/76

(52) U.S. Cl. CPC G03F 1/70; G02F 1/133516; G03F 1/76; G03F 7/20; G03F 7/0007; G02F 1/133512

(57) ABSTRACT

A photomask is used for scanning type projection exposure provided with a projection lens assembly composed of a lens assembly. A line width in a plurality of patterns of the photomask in a region to be transferred by performing scanning exposure including connecting portions of the lens assembly are corrected with respect to a line width of patterns which are the same as the patterns of the photomask present in a region to be transferred by performing scanning exposure but do not include the connecting portions.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2017/025967, filed on Jul. 18, 2017, which is based upon and claims the benefit of priority to Japanese Patent Application No. 2016-143333, filed on Jul. 21, 2016 and Japanese Patent Application No. 2016-238997, filed on Dec. 9, 2016; the disclosures of which are all incorporated herein by reference in their entireties.

### TECHNICAL FIELD

The present invention relates to a photomask, a method for producing a photomask, and a method for producing a color filter using a photomask.

### BACKGROUND ART

In recent years, the demand for liquid-crystal displays, particularly color liquid-crystal display panels, has remarkably increased with the increase in large-sized color televisions, laptop computers, and portable electronic devices. A color filter substrate used in a color liquid-crystal display panel is formed on a transparent substrate made of a glass through photolithography. In photolithography, a black matrix, colored pixels such as a red filter, a green filter, a blue filter and the like, and spacers and the like are patterned such as by pattern exposure and development, using a photomask.

In recent years, enlargement of a color liquid-crystal display itself is requested, and production efficiency is also requested to be enhanced. It is particularly important that the color filter substrate used in the color liquid-crystal display panel needs to increase the size of the mother glass, and efficiently produce a large multi-surface color filter substrate including a number of patterns for a large-sized display panel.

In a color liquid crystal display panel, a reflection type color liquid-crystal display device using an array substrate (silicon substrate) has also been proposed, on which elements such as colored pixels, a black matrix, a flattening layer, a spacer, and the like are formed.

In producing color filter substrates for these color liquid-crystal display devices, a one-shot exposure processing method using a one-shot exposure type photomask has often been employed to obtain high productivity. However, as the size of the photomask increases, which is caused by a further increase in substrate size, the technological problems of the one-shot exposure type photomask have increased, and has become expensive. That is, such problems in the one-shot exposure processing method are increasing. There is a method in which a resist (photosensitive resin solution) is applied to a glass substrate or a silicon substrate, and then the substrate is exposed while scanning, by using a small photomask which is inexpensive and easy to produce. The development of such a method (scanning exposure method) is advancing.

A solid-state image sensor incorporated in a digital camera or the like includes a plurality of image sensors on the surface of a silicon wafer having a diameter of approximately 30 cm. Then, the solid-state image sensor forms a large number of photoelectric conversion elements (CCD or CMOS) which configures the image sensors, and wiring, through the wafer process. Then, in order to capture color images, an OCF (On Chip Filter) layer which is composed of colored pixels for color separation and micro-lenses are formed on the photoelectric conversion element by photolithography. Then, in the dicing process, the wafer is cut to form a chip shaped (individual) solid-state image sensor. To apply the scanning exposure method to photolithography for forming the OCF layer, the development of the method is advancing.

FIG. 1 is a conceptual diagram showing a configuration of a scanning exposure type projection exposure apparatus (PTL 1). In this apparatus, exposure light 31 is irradiated from a light-source unit (not shown) installed on the upper portion of a photomask 32, and a resist applied to a substrate 34 is exposed through the patterned photomask 32 to form a black matrix, colored pixels, spacers, or a micro-lens pattern. A projection lens assembly 33 is formed of a lens assembly in which columnar lenses are staggered, and the center of the projection lens assembly 33 is on the center line in a scanning direction of the photomask 32. A stage 35 supports the substrate 34 and is movable in the scanning direction in synchronization with the photomask 32. The scanning direction of the photomask 32 is referred to as a Y direction, and a direction orthogonal to the Y direction and across the surface of the substrate 34 is referred to as an X direction. The columnar lenses of the projection lens assembly 33 are staggered in the Y direction. The resist is applied to the surface of the substrate 34.

For example, let us assume a case in which the photomask 32 has a size one-fourth of the substrate 34, and four-sided scanning exposure is performed with two surfaces in the X direction and two surfaces in the Y direction. First, the center of the photomask 32 is moved to coincide with the center of one of the regions obtained by dividing the surface of the substrate 34 into four (¼ region), and thus, an initial position is determined. After that, the photomask 32 and the substrate 34 are scanned simultaneously in the Y direction with respect to the fixed projection lens assembly 33. Then, the pattern formed on the photomask 32 is transferred to the resist of the ¼ region of the substrate 34. The photomask 32 is moved to each of the remaining three initial positions to repeat this operation. Accordingly, the pattern is transferred to the resist of the entire substrate 34.

In the projection exposure apparatus, a field stop for connecting the exposure regions of each columnar lens is inserted into the optical path of the light transmitted through the projection lens assembly 33. Thus, the exposure regions 36 of the projection lens assembly 33 are configured such that in plan view, trapezoidal regions, as shown partially in FIG. 2A are staggered. The adjacent trapezoidal regions are arranged in opposite directions to each other. Therefore, the connecting portion between the two adjacent columnar lenses when enlarged becomes as shown in FIG. 2B. That is, the exposure regions of the connecting portion are set so that in the edge of each columnar lens (that is, the edge of the trapezoidal region), triangle shapes face each other in the Y direction, and by scanning in the Y direction, the total amount of light transmitted through the two lenses of the connecting portion becomes equal to the amount of light through quadrilateral regions of the exposure regions, which do not include the connecting portion at any position in the X direction. In other words, if the amount of light transmitted through a quadrangular region which does not include a connecting portion is 100 (relative value, see FIG. 2B), the total amount of light transmitted through the two lenses of the connecting portion also becomes 100.

### CITATION LIST

### Patent Literature

PTL1: JP H11-160887 A

However, in the resist pattern line width on the actually transferred substrate 34, the line width formed using the light amount 100 in one exposure differs from the line width formed by using a total amount of 100 in two exposures. For example, if formed by using the negative resist, as shown in FIG. 2C, the line width formed by two exposures is thinner than the line width formed by one exposure, and becomes thinnest at the center of the connecting portion (portion where two exposures of a light amount 50+50 are performed). In the two exposure, there is a time lag between the two exposures. This is why the reactivity with respect to the light of the resist becomes lower compared with the case where one exposure is performed. If the sensitivity of the resist is increased as a countermeasure to this problem, the same phenomenon occurs, and the difference in the line width appears unevenly on the color filter substrate. Thus, the problem is not solved. A negative resist refers to a resist in which solubility of the exposed portion in the developing solution is reduced, and the exposed portion remains after being developed. A positive resist refers to a resist in which solubility of the exposed portion in the developing solution is increased, and the exposed portion is removed after being developed.

More specifically, with reference to FIGS. 3A and 3B, a description will be given of a case in which colored pixels for a color filter substrate are formed by the exposure apparatus. In other words, in FIG. 3A, the reactivity of the resist gradually decreases as L1, L2, L3, . . . Ln toward the center, in the X direction of the connecting portion 36a of the two columnar lenses. Therefore, if the colored pixels are formed by using a negative resist, as shown in FIG. 3B, the line width in the X direction of the colored pixels becomes thinner in the order of the resist patterns C1kx, C2kx, . . . Cnkx (k=1, 2, . . . n). Similarly, the line width in the Y direction decreases in the order of resist patterns Ck1y, Ck2, . . . Ckny (k=1, 2, . . . n). If colored pixels are formed by using a positive resist, that is, by using a reverse mask of a negative resist, the line width becomes thicker in the above order. Reference number 38 in FIG. 3B indicates a photomask having a colored pixel pattern, which in the present description indicates a photomask for a negative resist. In other words, each region Cnn is a light transmission region (opening). The reference number SA1 in FIG. 3B (and FIG. 4B, described later) indicates scanning regions not including the connecting portions (scanning regions only including the above-described quadrangular areas), and the reference number SA2 indicates scanning regions including the connecting portions.

Formation of the black matrix for a color filter substrate by using the exposure apparatus results in the illustration shown in FIGS. 4A and 4B. That is, if the black matrix is formed by using the negative resist, as shown in FIG. 4B, the X-direction line width of the black matrix becomes thinner in the order of bx1, bx2, . . . bxn. Similarly, the Y direction line width becomes thinner in the order of by1, by2, . . . byn. If the black matrix is formed by using the positive resist, that is, by using a reverse mask of the negative resist, the line width becomes thicker in the above order. Reference number 39 in FIGS. 4A and 4B indicates a photomask having a black matrix pattern, which refers to a photomask for a negative resist. That is, each region Bxn is a light transmission region (opening) extending in the Y direction, and each region Byn is a light transmission region (opening) extending in the X direction. The line width of the region Bxn is shown by bxn, and the line width of the region Byn is indicated by byn.

### SUMMARY OF THE INVENTION

### Technical Problem

The present invention has been made to improve and even solve the above problems, and an object of the present invention is to provide a photomask, a method of producing a photomask, and method of producing a color filter using the photomask, that in scanning exposure type projection exposure, to improve or even solve the problem of an abnormal line width caused by a connecting portions in a projection lens assembly (narrowing of the line width in the case of forming colored pixels, a black matrix, a spacer, or a micro-lens with a negative resist, and increasing of the line width in the case of forming with a positive resist).

### Improvement to the Problem

To improve or even solve the above problems, a photomask according to a first aspect of the present invention is used for scanning type projection exposure using a projection lens assembly composed of a lens assembly, wherein a line width in a plurality of patterns of the photomask present in a region to be transferred by performing scanning exposure including connecting portions in the lens assembly is corrected with respect to a line width of patterns which are the same as the patterns of the photomask present in a region to be transferred by performing scanning exposure but do not include connecting portions.

A photomask according to a second aspect of the present invention is the photomask according to the first aspect described above, wherein the corrected line width of the plurality of patterns changes stepwise in a direction orthogonal to a scanning direction for each of the patterns.

A photomask according to a third aspect of the present invention is the photomask according to the second aspect described above, wherein the corrected line width of the plurality of patterns further changes stepwise in the scanning direction for each of the patterns.

A photomask according to a fourth aspect of the present invention is the photomask according to the second aspect or third aspect described above, wherein the line width that changes stepwise includes a correction component based on a random number.

A photomask according to a fifth aspect of the present invention is a photomask on which first light transmitting parts linearly extending in a direction along a first coordinate axis in plan view, and second light transmitting parts linearly extending in a direction along a second coordinate axis crossing the first coordinate axis in plan view are formed. In the photomask, first regions in a direction along the first coordinate axis include first light transmitting parts having a first constant line width and second light transmitting parts having a constant second line width, and second regions in a direction along the first coordinate axis include first light transmitting parts having a third line width which is wider than the first line width and second light transmitting parts having a fourth line width which is wider than the second line width. The first regions and the second regions are alternately arranged in a direction along the first coordinate axis.

A method for producing the photomask according to a sixth aspect of the present invention is for forming optical images used in an exposure apparatus in which an exposure object is exposed, by using optical images obtained using a plurality of projection optical systems staggered along a first axis in the plan view, and by scanning the exposure object in a direction along a second axis which intersects the first axis; including steps of setting a first coordinate axis corresponding to the first axis and a second coordinate axis corresponding to the second axis on a photomask-forming body, and creating drawing data for turning on and off a scanning beam on the photomask-forming body, according to a shape of an exposure pattern on the exposure object, dividing the surface of the photomask-forming body into regions for single exposure where scanning in a direction along the second axis is performed using the first optical images from a single first projection optical system or the second optical images by a single second projection optical system from the plurality of projection optical systems in the exposure apparatus, and regions for combined exposure where scanning in a direction along the second axis is performed using the first and second optical images from the first and second projection optical systems, separately setting beam intensity data of the scanning beam for the regions for single exposure and the regions for combined exposure, and applying a resist on the photomask-forming body, and scanning the scanning beam that is driven based on the drawing data and the beam intensity data on the resist. Moreover, the beam intensity data is set to a first beam intensity in the regions for single exposure, and the beam intensity data is set to a second beam intensity different from the first beam intensity at edge scanning positions, which are adjacent to scanning positions for turning off the scanning beam, to turn on the scanning beam, in the regions for combined exposure.

A method for producing the photomask according to a seventh aspect of the present invention is the method for producing the photomask according to the sixth aspect described above, wherein the second beam intensity is higher intensity than the first beam intensity.

A method for producing the photomask according to an eighth aspect of the present invention is the method for producing the photomask according to the seventh aspect described above, wherein the beam intensity data is set to a third beam intensity that is no less than the first beam intensity and no greater than the maximum value of the second beam intensity at scanning positions other than the edge scanning positions in the regions for combined exposure.

A method for producing the photomask according to a ninth aspect of the present invention is the method for producing the photomask according to the eighth aspect described above, wherein the third beam intensity is equal to the first beam intensity.

A method for producing the photomask according to a tenth aspect of the present invention is the method for producing the photomask according to any one of the sixth to ninth aspects described above, wherein the second beam intensity is set as a function of λ expressed by the following equation (1) when an exposure ratio of the first optical images is taken to be E1 and an exposure ratio of the second optical images is taken to be E2, at the edge scanning positions.

$$\begin{matrix}[ Equation 1 ] & \\ λ = \frac{\vert E 1 - E 2 \vert}{E 1 + E 2} & ( 1 )\end{matrix}$$

A method for producing the photomask according to an eleventh aspect of the present invention is the method for producing the photomask according to the tenth aspect described above, wherein the second beam intensity takes a maximum value at λ=0 and approaches the first beam intensity as λ changes from 0 to 1.

A method for producing the photomask according to a twelfth aspect of the present invention is the method for producing the photomask according to the sixth aspect described above, wherein the second beam intensity is lower intensity than the first beam intensity.

A method for producing the photomask according to a thirteenth aspect of the present invention is the method for producing the photomask according to any one of the sixth to twelfth aspects described above, wherein the drawing data is set to turn on the scanning beam in a lattice-shaped region extending along the first coordinate axis and the second coordinate axis.

A method for producing a color filter according to a fourteenth aspect of the present invention uses a scanning type projection exposure which includes a projection lens assembly composed of a lens assembly, wherein a pattern exposure is performed on a resist provided on a glass substrate or a silicon substrate by using a photomask according to any one of claims 1 to 4.

### Desired Effect of Invention

With the photomask according to the present invention, the line width in a plurality of patterns of the photomask present in the region to be transferred by performing scanning exposure including the connecting portions in the lens assembly is corrected with respect to the line width of the patterns which are the same as the patterns of the photomask present in the region to be transferred by performing scanning exposure but do not include the connecting portions. In this way, the problem of line width abnormality is improved or even solved which is caused by the connecting portions in the projection lens assembly, in the scanning exposure. Moreover, with the production method using the photomask according to the present invention, colored pixels, black matrices, spacers and micro-lenses can be produced which have good uniformity of line width (dimension). Therefore, unevenness is not visually recognized on the color filter substrate or the silicon substrate.

### BRIEF DESCRIPTION OF THE DRAWINGS

FIG. 1 is a conceptual diagram showing a configuration of a scanning exposure type projection exposure apparatus.

FIGS. 2A, 2B, and 2C are schematic views showing an exposure state of the projection exposure apparatus of FIG. 1, in which FIG. 2A is a plan view partially showing the shape of light transmitted through the projection lens assembly, FIG. 2B is a partially enlarged view of FIG. 2A, and FIG. 2C is a characteristic diagram for describing a change of the line width of the negative resist pattern in the X direction position, formed in the FIG. 2B region by scanning exposure.

FIGS. 3A and 3B are plan views used to describe the condition when colored pixels are formed by the projection exposure apparatus of FIG. 1, in which FIG. 3A is a partially enlarged view of the shape of the light transmitted through the projection lens assembly, and FIG. 3B is a partially enlarged view of a photomask for a negative resist.

FIGS. 4A and 4B are plan views used to describe the condition when a black matrix is formed by the projection exposure apparatus in FIG. 1, in which FIG. 4A is a partially enlarged view of the shape of the light transmitted through the projection lens assembly, and FIG. 4B is a partially enlarged view of a photomask for a negative resist.

FIGS. 5A, 5B, 5C, and 5D are views for describing a method of correcting a mask pattern line width for forming colored pixels by using the photomask of the first embodiment of the present invention.

FIGS. 6A, 6B, 6C, and 6D are views for describing a method of correcting a mask pattern line width for forming a black matrix by using the photomask of the first embodiment of the present invention.

FIGS. 7A and 7B are views for describing a method of correcting a line width by dividing a mask pattern for forming colored pixels by using the photomask of the first embodiment of the present invention.

FIG. 8 is a plan view showing an example of colored pixels divided in the X direction and the Y direction, respectively.

FIG. 9 is a schematic plan view showing an example of a photomask according to a second embodiment of the present invention.

FIG. 10 is a schematic enlarged view showing a configuration of regions for single exposure in the photomask according to the second embodiment of the present invention.

FIG. 11 is a schematic enlarged view showing a configuration of regions for combined exposure in the photomask according to the second embodiment of the present invention.

FIG. 12 is a schematic front view showing an example of an exposure apparatus in which the photomask according to the second embodiment of the present invention is used.

FIG. 13 is a plan view as viewed from A of FIG. 12.

FIG. 14 is a schematic plan view showing an example of a field stop used in the exposure apparatus.

FIG. 15 is a schematic plan view showing another example of the field stop used in the exposure apparatus.

FIG. 16 is a schematic diagram for describing an exposure operation performed by the exposure apparatus.

FIGS. 17A and 17B are schematic diagrams for describing an effective exposure dose in the exposure apparatus.

FIG. 18 is a schematic graph for describing an example of beam intensity of a scanning beam used in a method for producing the photomask according to the second embodiment of the present invention.

FIG. 19 is a schematic diagram showing a method for setting beam intensity data, in the method for producing the photomask according to the second embodiment of the present invention.

FIG. 20 is a flowchart showing an example of the method for producing the photomask according to the second embodiment of the present invention.

FIGS. 21A, 21B, 21C, and 21D are schematic diagrams showing examples of setting beam intensity data in the method for producing the photomask according to the second embodiment of the present invention.

FIGS. 22A, 22B, 22C, 22D, and 22E are process explanatory diagrams for the method for producing the photomask according to the second embodiment of the present invention.

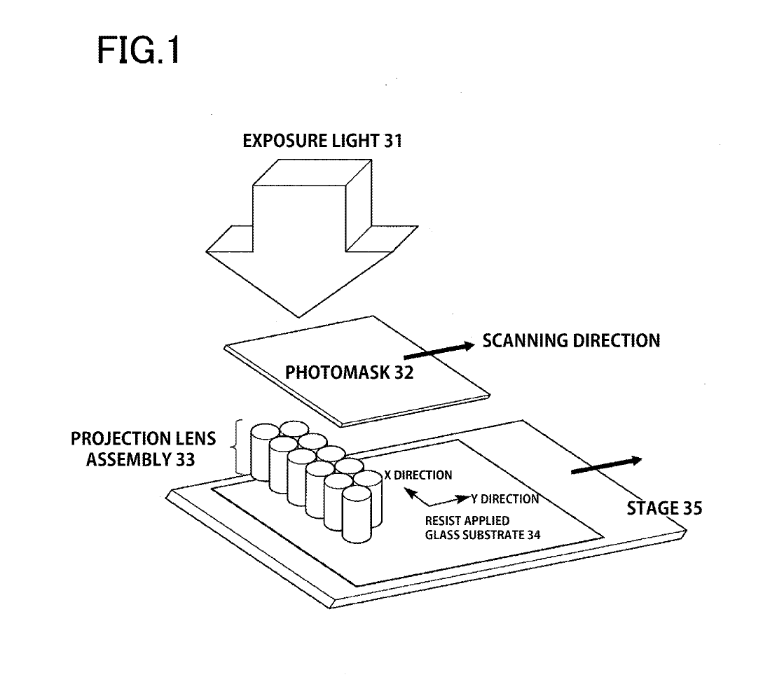

### DESCRIPTION OF REPRESENTATIVE EMBODIMENTS

### First Embodiment

With reference to the drawings, a description will now be given of a first embodiment of a photomask according to the present invention. The present invention is not limited to the following representative embodiments, and appropriate modifications can be made without departing from the spirit of the present invention. The representative embodiments described below are merely examples of the present invention, and the design thereof could be appropriately changed by one skilled in the art. The same constituent elements are denoted by the same reference numerals unless there is a reason for the sake of convenience, and redundant description is omitted. In the drawings referred to in the following description, for clarity, characteristic parts are enlarged, and thus the components are not shown to scale.

The photomask of the present invention can be applied to a method of producing a color filter substrate or a silicon substrate on which colored pixels or a black matrix are formed, and applied to a method of producing an OCF layer in which micro-lenses are formed. However, for simplicity, in the following, these producing methods are collectively referred to as method for producing a color filter.

In the following, unless otherwise specified, a description will be given of a case in which the colored pixels and the black matrix are formed by using a negative resist. The difference between forming the colored pixels and the black matrix by using the negative resist and the positive resist is the reversal of the opening parts (light transmitting parts) and the light shielding parts of the photomask, and the content of correcting the line width of the opening parts (if formed by the negative resist, the line width is corrected to be thicker, and if formed by the positive resist, the line width is corrected to be thinner).

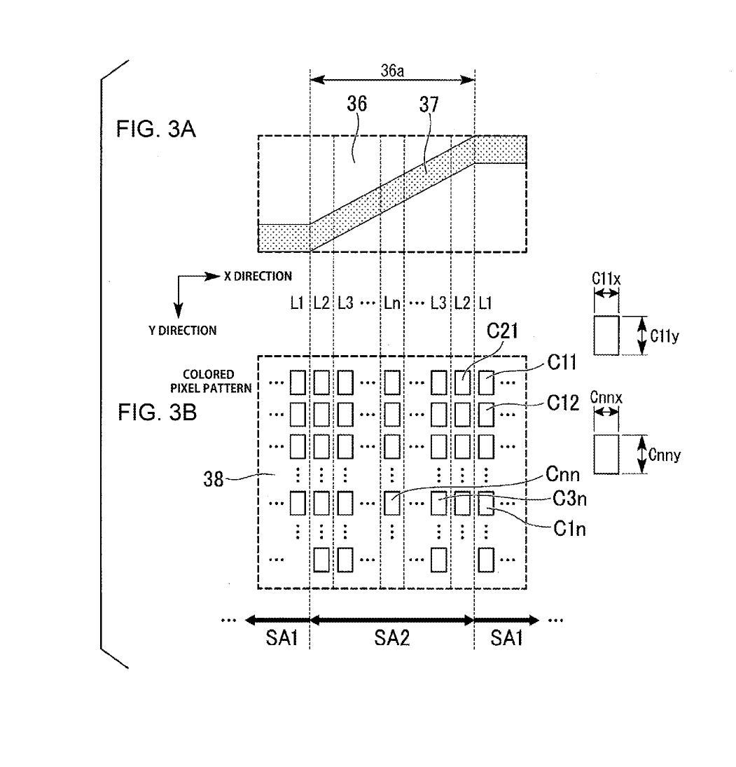

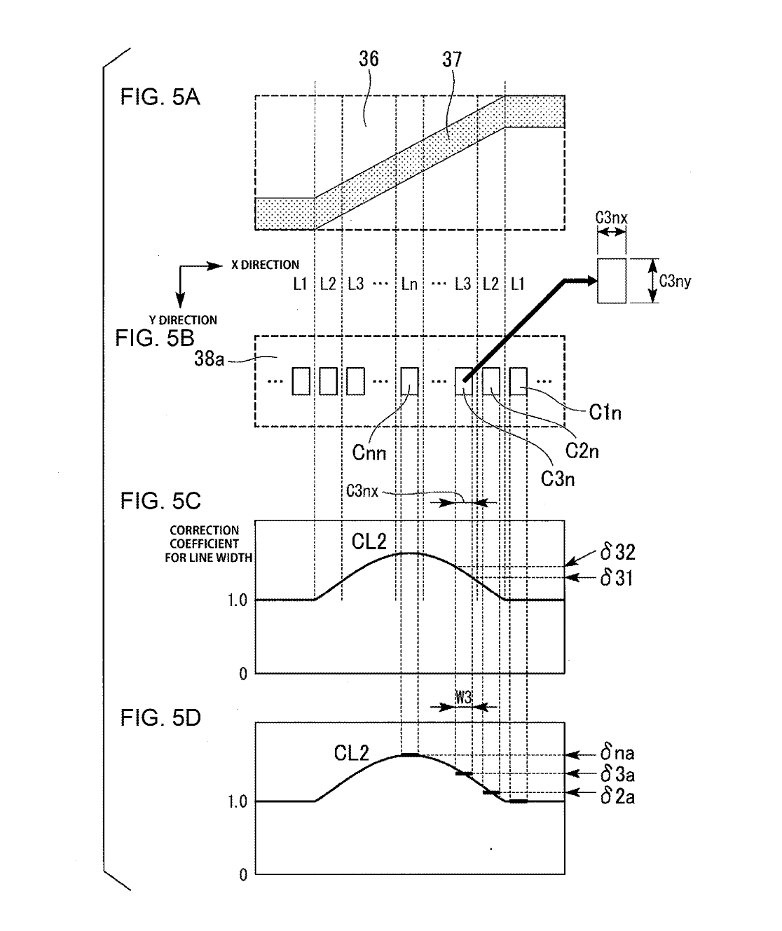

FIGS. 5A and 5B are views for describing a method of correcting a mask pattern line width for forming the colored pixels by using the photomask of the present invention. FIG. 5A shows a region equivalent to that shown in FIG. 3A, that is, FIG. 5A shows the plan view shape of exposure regions 36 and a light shielding region 37 caused by the light transmitted through the projection lens assembly. This means the reactivity of the resist gradually decreases toward the center of the connecting portion between the two columnar lenses in the X direction, that is, in the order of L1, L2, L3, . . . , Ln.

FIG. 5B is a plan view of a photomask 38a of the present invention having a colored pixel pattern, however, to simplify the explanation, of the pattern arrangement of FIG. 3B, only the patterns C1n, C2n, C3n, . . . , Cnn arranged in the X direction are shown. C1n, C2n, . . . , Cnn indicate each opening pattern, and as described above, in C1n, exposure is performed by one exposure of a relative light amount of 100, however, the reactivity of the resist due to the transmitted light decreases in the order of C2n, C3n, . . . , Cnn, that is, the line width of the colored pixels in the X direction and the Y direction becomes thinner. In other words, the opening pattern Cnn is at a position corresponding to the center of the connecting portion between the two columnar lenses in the X direction.

Therefore, in the photomask of the present invention, the line width (opening pattern width) of C2n, C3n, . . . , Cnn are produced so that the line width is corrected to be gradually larger in the above order, to thereby improve the above problem of the line width thinning. This method is effective because in the exposure apparatus using the photomask of the present invention, the center of the projection lens assembly 33 is on the center line in the scanning direction of the photomask 32. This means the position on the photomask where the line width abnormality occurs is fixed.

That is, the line width in a plurality of patterns of the photomask in the region to be transferred by performing scanning exposure including the connecting portions in the lens assembly 33 is corrected with respect to the line width of the patterns which are the same as the above patterns of the photomask which are present in the region to be transferred by performing scanning exposure but do not include the connecting portions.

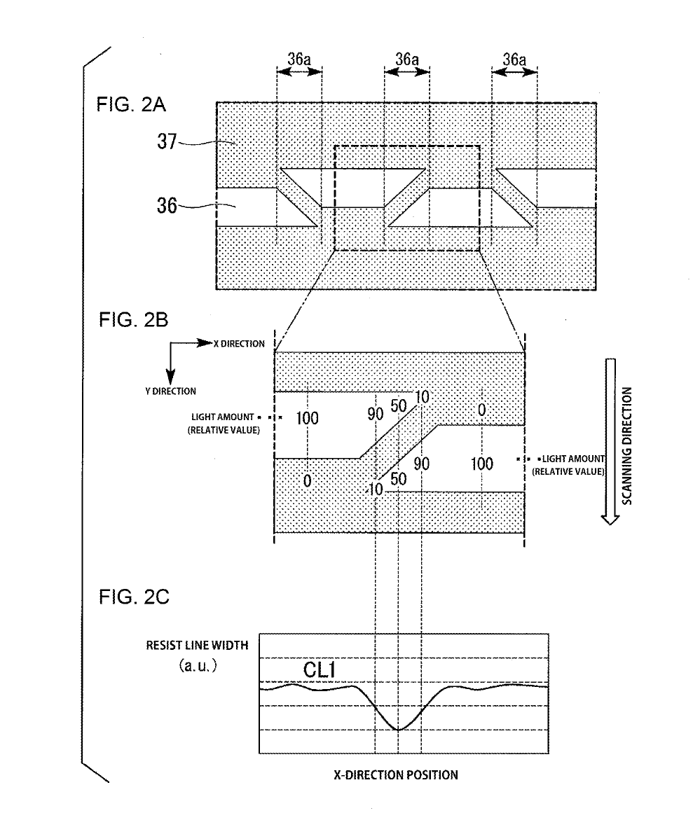

More specifically, a value obtained by multiplying the line width of C1n by a correction coefficient is set to be the line width of C2n and afterward. The value of the correction coefficient is based on the line width of C1n when a resist pattern equal to the designed line width is obtained. That is, the characteristic curve CL1 (see FIG. 2C) at this time is smoothed, and a correction curve CL2 (FIG. 5C) is created to obtain a design line width pattern. The vertical axis of FIG. 5C represents a value obtained by dividing the measurement line width of C1n by the measurement line width of the resist pattern, such a resist pattern being formed by using each opening pattern when all the opening patterns are equal.

A perpendicular line (a line in the vertical direction of the drawing) is drawn from positions of both sides of C2n, C3n, . . . , Cnn in the X direction to the correction curve CL2, and two intersections of the correction curve CL2 and each line (for example, δ31 and δ32 for C3n) are obtained. Then, the average value of the correction coefficients at the two intersections (63a for C3n, and the average value is substantially the intermediate value between δ31 and δ32 because the change in the correction curve CL2 is linear in a small region) is taken to be the correction coefficient for C2n, C3n, . . . , Cnn (see FIG. 5D). Thus, the correction coefficient for C1n is 1.0 (no correction), and the correction coefficients for C2n, C3n, . . . , Cnn are substantially the inverse of the ratio of the measured line width, and a line width of the corrected opening pattern is the line width that changes stepwise for each pattern in a direction orthogonal to the scanning direction (X direction). Therefore, when scanning exposure is performed using the photomask of the present invention, the line width of colored pixels after being exposed becomes uniform.

For convenience of drawing, the above correction curve CL2 is for correcting the line width C2nx, C3nx, . . . , Cnnx in the X direction of C2n, C3n, . . . , Cnn, but the correction curve CL2 is also effective for correcting the line width C2ny, C3ny, . . . , Cnny in the Y direction. This is because the ratio of the resist reactivity in each pixel is the same in both the X direction and the Y direction. This means, when the resist pattern line width of C1ny, C2ny, C3ny, . . . , Cnny in the Y direction are measured, a shape similar to the characteristic curve CL1 of FIG. 2C is obtained. Therefore, the correction curve CL2 for correction in the Y direction is the same as that for the line width in the X direction, and the value of the correction coefficient in the Y direction for each pixel depends only on the position in the Y direction of C2n, C3n, . . . Cnn. In this way, in the photomask of the present invention, the corrected line width changes stepwise for each pixel in the scanning direction, and the line width of the colored pixels after being exposed also becomes uniform in the scanning direction.

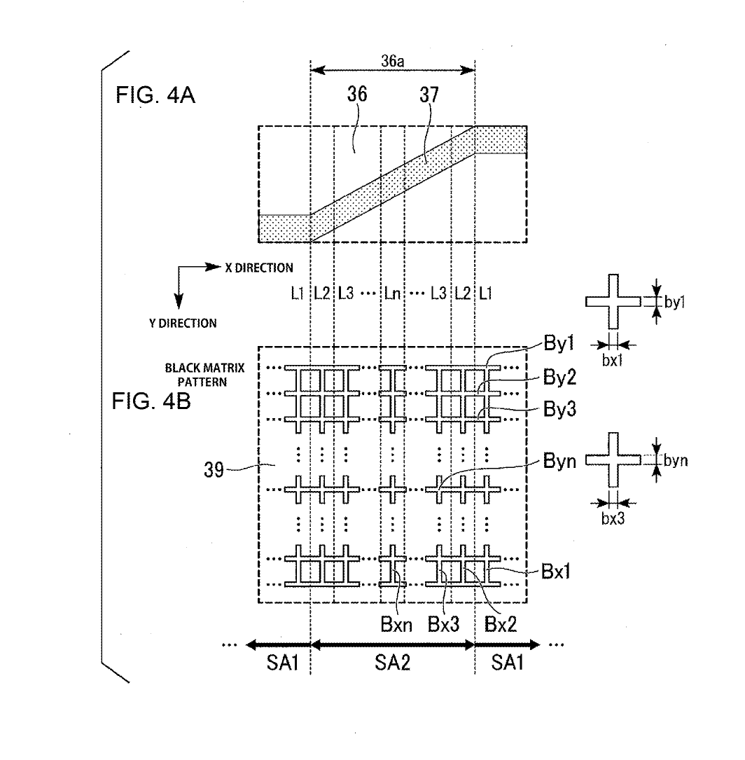

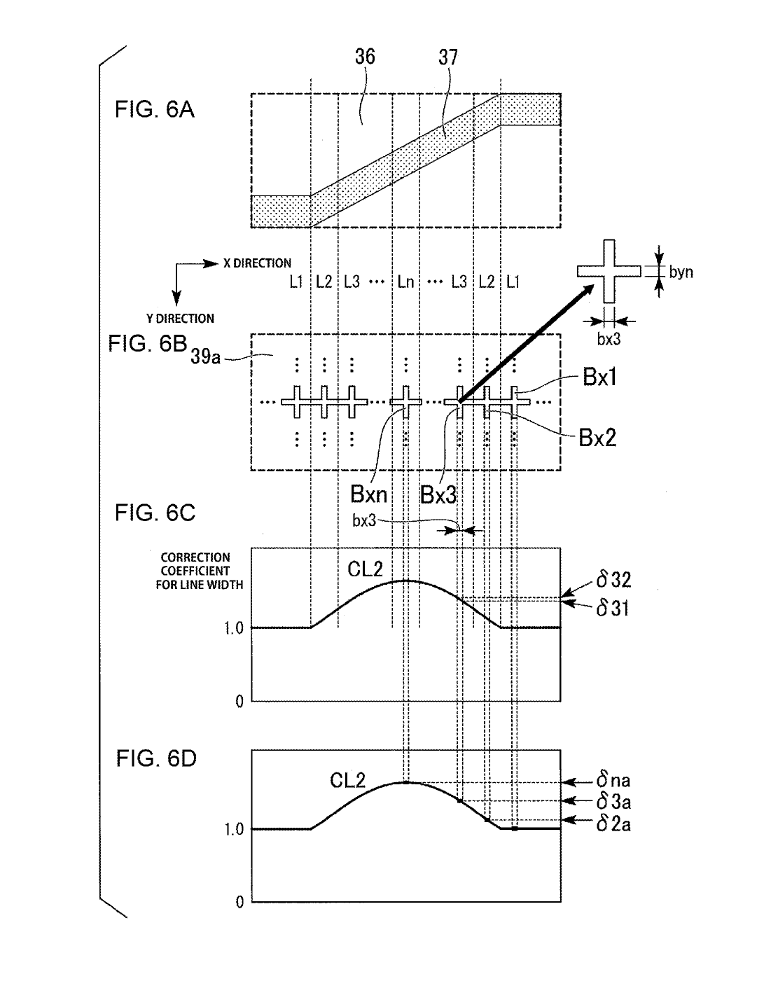

The photomask of the present invention for forming colored pixels has been described above, and the same applies to a photomask for forming a black matrix. FIGS. 6A, 6B, 6C, and 6D are views for explaining a method of correcting mask pattern line width for forming a black matrix by using the photomask of the present invention. The difference between forming the colored pixels and forming the black matrix is that in the case of colored pixels, line width in the X direction and the Y direction is corrected for individual pixels, however, in the case of the black matrix, Bx2, Bx3, . . . Bxn arranged in the X direction are corrected for the line width bx2, bx3, . . . bxn in the X direction, respectively, and By2, By3, . . . Byn arranged in the Y direction (see FIG. 4B) are corrected for the line width by2, by3, . . . byn in the Y direction, respectively.

In the case of Bx2, Bx3, . . . Bxn in the X direction, a perpendicular line (a line in the vertical direction of the drawing) is drawn from both sides of each of Bx2, Bx3, . . . Bxn to the correction curve CL2, and two intersections of the correction curve CL2 and each line (δ31 and δ32 for Bx3) are obtained. Then, the average value of the correction coefficients at the two intersections (δ3a for Bx3) is taken to be the correction coefficient for Bx2, Bx3, . . . Bxn (FIG. 6D). Thus, the correction coefficient for Bx1 is 1.0 (no correction), and the correction coefficients for Bx2, Bx3, . . . Bxn are substantially the inverse of the ratio of the measured line width. Accordingly, if scanning exposure is performed using the photomask of the present invention, the line width of the black matrix after being exposed becomes uniform. The same also applies to By1, By2, . . . Byn in the Y direction.

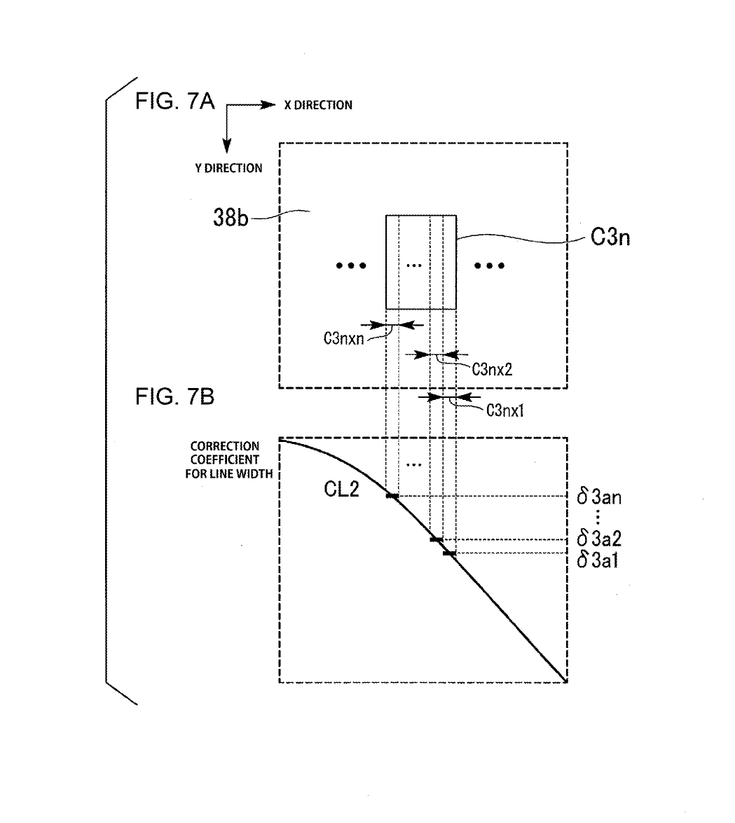

In the method of correcting the line width of the photomask of the present invention, one mask pattern may be divided to correct the line width. FIGS. 7A and 7B are views for describing a method of correcting line width by dividing a mask pattern for forming the colored pixels by using the photomask of the present invention. FIGS. 7A and 7B representatively show the case where the C3n pixel of FIG. 5B divided in the X direction. In this way, one mask pattern corresponding to one pixel is divided into n portions. Then, for each portion, correction coefficients δ3a1, δ3a2, . . . δ3an are obtained by using the correction curve CL2 similarly to the case of FIGS. 5A, 5B, 5C, and 5D. By doing this, the stepwise change of the line width caused by the correction becomes small, and thus, close to the curve. This means, the measures against the line width abnormality are taken to be more practical, so the line width uniformity of the colored pixels after being exposed is further improved.

Similarly, the method of correcting the pattern by being divided can also be performed in the Y direction of the colored pixels, and in the X and Y directions of the black matrix. The method is effective for improving the line width uniformity. Normally, the dimensions of a black matrix are smaller than the line width of colored pixels in the width direction, and larger than the line width of the colored pixels in the length direction. This is why, it is preferable that the number of divisions in the width direction is less than that of the colored pixels, and the number of divisions in the length direction be greater than that of the colored pixels.

In the photomask of the present invention, by introducing the above-described line width correction, the line width abnormality that occurs due to the connecting portions of the projection lens assembly can be improved. However, as the fluctuation (irregularity) of the line width measurement values of FIG. 2C describes, the line width abnormality caused by the connecting portions in the projection lens assembly is not always stable. Therefore, in the photomask of the present invention, the line width that changes stepwise by being corrected can include a correction component based on a random number. As a result, the line width further improves its uniformity.

To produce the photomask, normally an electron beam drawing apparatus is used, and a pattern is created based on electron beam drawing data being produced. Therefore, the correction component based on the random number is introduced to the corrected line width by the drawing data being changed.

The correction component based on the random number can be introduced into the corrected line width by using the method described in JP 2011-187869 A. JP 2011-187869 A describes resizing (line width adjustment) caused by the introduction of a random number into drawing data. The purpose of the resizing is to mitigate the variations of the line width and the positional accuracy of the mask pattern generated by the drawing method peculiar to the drawing device. On the other hand, the photomask of the present invention is different from the prior art in that the photomask of the present invention is for the instability of the line width abnormality caused by the connecting portions in the projection lens assembly as described above.

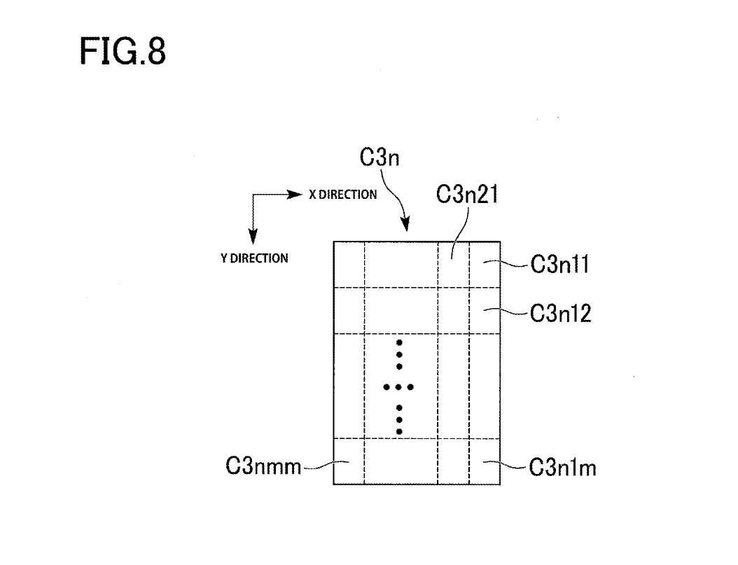

More specifically, the introduction of the correction component based on the random number to the corrected line width in the photomask of the present invention can be performed by adding or subtracting (plus or minus) a second correction coefficient that is generated by a random number based on the above-described correction coefficient used for changing the line width stepwise. With respect to a mesh unit mentioned in JP 2011-187869 A, when the colored pixels are formed, the unit used in the photomask of the present invention may be either each of the pixels of FIG. 3B without being divided, or each of the pixels being divided in the X direction as shown in FIGS. 7A and 7B, or in the X or Y directions as shown in FIG. 8. The same applies to the case of the black matrix, however, particularly in the length direction, it is effective to set the mesh unit of the pixels after being divided.

The amplitude of the range for the second correction coefficient generated by the random number may be determined by experimental results, so that a suitable range is obtained. Note that it is preferable to set the range of the amplitude to be the same magnitude on the positive or negative side, based on the correction coefficient used for changing the line width stepwise as the base value. A process of reallocating the random number if plus or minus numbers consecutively appear, and other data processes may be performed similarly to the method shown in JP 2011-187869 A.

The above-described photomask of the present invention can improve or even solve the problem of line width abnormality caused by the connecting portion in the projection lens assembly: by introducing the correction coefficient to change the line width stepwise, the stationary component of the line width abnormality arising from the connecting portions in the projection lens assembly is reduced; furthermore, by introducing the second correction coefficient that is generated using the random number, the unstable component of the line width abnormality caused by the connecting portions in the projection lens assembly is alleviated.

A method for producing a color filter of the present invention can produce a color filter by using a conventional method, except that the photomask of the present invention is used. With this method, colored pixels, a black matrix, spacers, and micro-lenses having good line width (dimension) uniformity can be produced. Accordingly, unevenness on the color filter substrate, the color filter layer on the array substrate, or on the silicon substrate will no longer be visually recognized.

### Second Embodiment

A description will now be given of a photomask according to a second embodiment of the present invention.

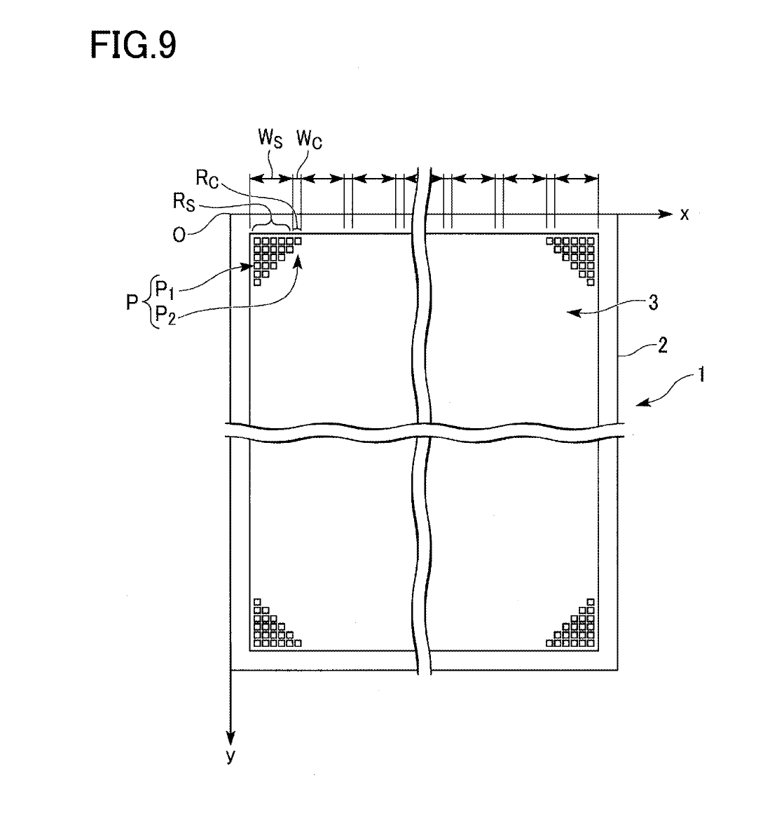

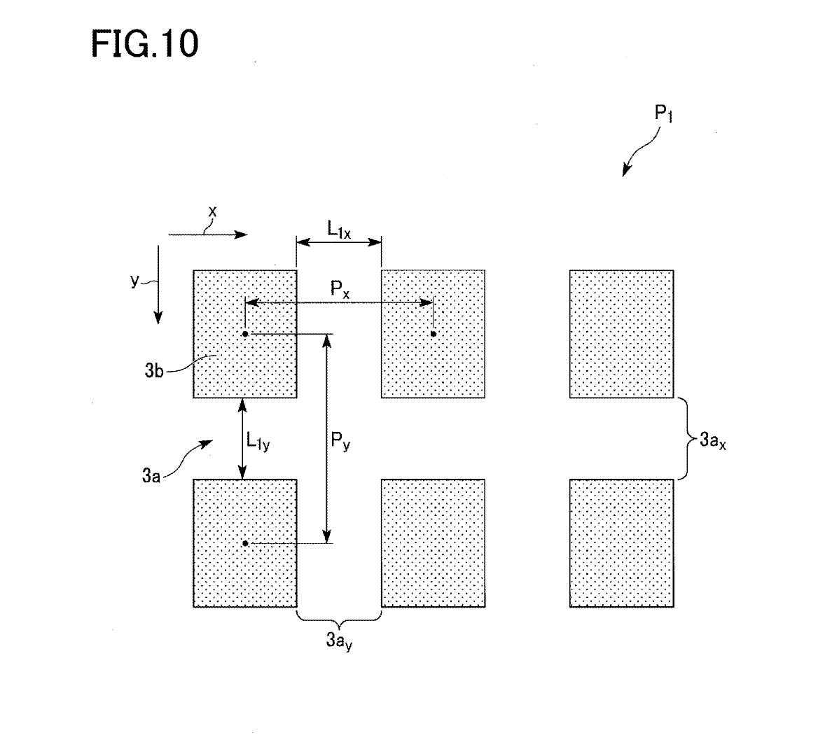

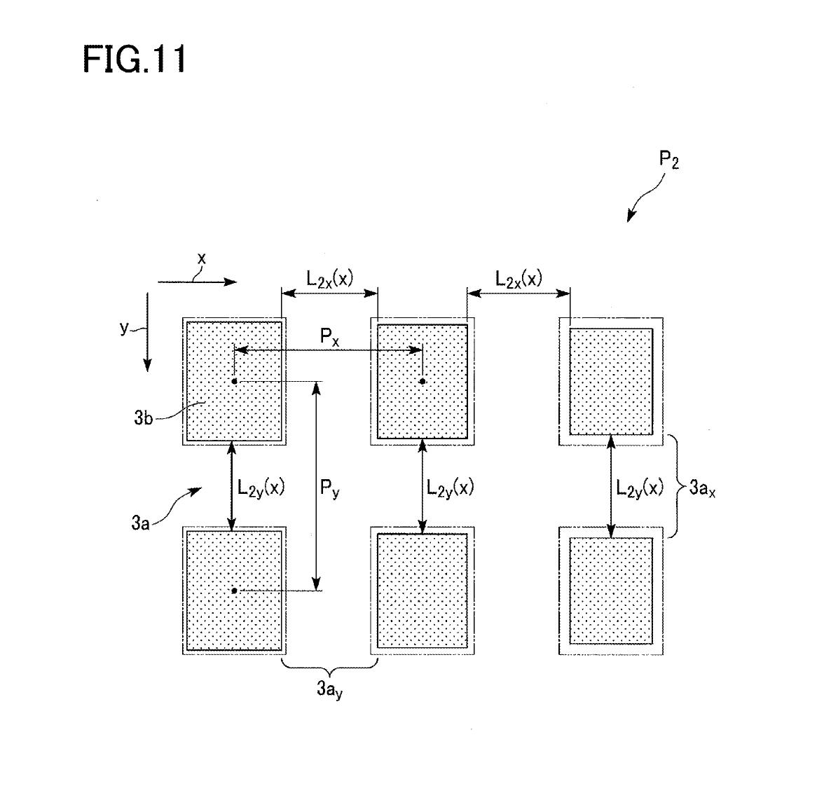

FIG. 9 is a schematic plan view showing an example of the photomask according to the second embodiment of the present invention. FIG. 10 is a schematic enlarged view showing a configuration of regions for single exposure of the photomask according to the second embodiment of the present invention. FIG. 11 is a schematic enlarged view showing a configuration of regions for combined exposure in the photomask according to the second embodiment of the present invention.

Because each drawing is a schematic diagram, the shape and dimensions may be enlarged (the same applies to the following drawings).

As shown in FIG. 9, the photomask 1 of the present embodiment is a mask for exposure used in the exposure apparatus which performs unmagnified exposure by using a plurality of projection optical systems. The photomask 1 includes a light transmitting substrate 2 and a mask part 3.

The light transmitting substrate 2 may be an appropriate substrate having light transparency capable of transmitting illuminated light of the exposure apparatus described later. For example, the light transmitting substrate 2 may be made of a glass substrate. The outer shape of the light transmitting substrate 2 is not particularly limited. In the example shown in FIG. 9, the outer shape of the light transmitting substrate 2 is a rectangular shape in plan view.

The mask part 3 includes a mask pattern P serving as an exposure pattern which is projected onto the exposure object (e.g., the substrate for producing the color filter) by the exposure apparatus. The mask pattern P is configured, for example, by a light shielding layer such as metal laminated on the patterned light transmitting substrate 2.

Generally, the mask pattern used for the exposure apparatus for equal magnification exposure may be identical in shape and size with the exposure pattern formed on the exposure object. However, the mask pattern P of the present embodiment has different shapes or sizes of the exposure pattern depending on the location.

On the surface of the light transmitting substrate 2, the mask pattern P is two-dimensionally formed in the y direction along the long side of the light transmitting substrate 2 and in the x direction along the short side of the light transmitting substrate 2. If the light-transmitting substrate 2 is a square in plan view, the x direction is along one of the two sides connected with each other in the light transmitting substrate 2, and the y direction is along the other of the two sides.

In order to describe the position of the mask pattern P on the light transmitting substrate 2, the x direction assumes an x-coordinate axis (first coordinate axis), and the y direction assumes a y-coordinate axis (second coordinate axis). In FIG. 9, as an example, the x-coordinate axis and the y-coordinate axis are set such that an apex of the exterior shape of the light transmitting substrate 2 serves as an origin O of the xy coordinate system. However, the origin O of the xy coordinate system may be set at an appropriate position on the light transmitting substrate 2.

The mask pattern P is composed of a pattern P₁ formed identical in shape with the exposure pattern to be formed on the exposure object, and a pattern P₂ formed to be a shape in which the above exposure pattern is corrected.

The pattern P₁ has a width Wₛ in the x direction, and is formed in regions for single exposure R_{S} (first region) that extend as a band in the y direction.

The pattern P₂ has a width W_{c} in the x direction, and is formed in regions for combined exposure R_{C} (second region) that extend as a band in the y direction.

The regions for single exposure R_{S} and the regions for combined exposure R_{C} are alternately arranged in the x direction. The size and arrangement pitch of the regions for single exposure R_{S} and the regions for combined exposure R_{C} are appropriately determined according to the configuration of the projection optical systems for the exposure apparatus described later.

The following description will be given by way of an example in which W_{S} and W_{C} (W_{C}<W_{S}) are both fixed values. Therefore, the arrangement pitch of the regions for single exposure R_{S} and the regions for combined exposure R_{C} in the x direction is W_{S}+W_{C}.

The specific shape of the mask pattern P is an appropriate shape required for the exposure pattern.

In the following, as an example of the mask pattern P, a description will be provided by way of an example in which the plan view shape of the light transmitting part through which the illumination light of the exposure apparatus passes is a rectangular lattice. Such an exposure pattern of the rectangular lattice shape may be used to form, for example, the black matrix (BM) used for a color filter of a liquid-crystal device.

FIG. 10 shows an enlarged view of the pattern P₁ in the single exposure region R_{S}.

The pattern P₁ is such that the light shielding parts 3b having a rectangular shape in plan view are arranged in a rectangular lattice shape in the x direction and the y direction. For example, the arrangement pitch of the light shielding parts 3b is Pₓ in the x direction and P_{y} in the y direction. For example, if the photomask 1 is used for forming BM, the pitch Pₓ (P_{y}) is in agreement with an arrangement pitch of the sub pixels in the x direction (y direction).

Between the light shielding parts 3b, a light transmitting part 3a is formed in which the surface of the light transmitting substrate 2 is exposed. The light transmitting part 3a is divided into a first linear part 3ax (first light transmitting part) extended in the x direction, and a second linear part 3a_{y} (second light transmitting part) extended in the y direction. That is, the light transmitting part 3a includes the first linear part 3ax and the second linear part 3a_{y}.

In the single exposure region R_{S} of the present embodiment, the first linear part 3aₓ includes a constant line width L_{1y} (the first line width, line width in the y direction). The second linear part 3a_{y} is a constant line width L₁ₓ (the second line width, line width in the x direction). For example, if the photomask 1 is used for forming BM, the line widths L_{1y} and L₁ₓ are equal to the line widths of the BM in they direction and the x direction, respectively.

FIG. 11 shows an enlarged view of the pattern P₂ in the combined exposure region R_{C}.

Similar to the pattern P₁, the pattern P₂ is such that the light shielding parts 3b having a rectangular shape in plan view are arranged in a rectangular lattice shape in the x direction and the y direction. For example, the arrangement pitch of the light shielding parts 3b is Pₓ in the x direction and P_{y} in the y direction. However, in the pattern P₂, the size of the light shielding parts 3b is different from that in the pattern P₁. In FIG. 11, to compare the pattern P₂ with the pattern P₁, the shape of the light shielding parts 3b in the single exposure region R_{S} (pattern P₁) is indicated by a dash-dot-dot line.

Therefore, in the pattern P₂, the first linear part 3aₓ and the second linear part 3a_{y}, of the light transmitting part 3aₓ, have the line width different from those in the pattern P₁.

In the combined exposure region R_{C}, the first linear part 3aₓ includes the line width L_{2y}(x) (the third line width) that changes in the x direction. The second linear part 3a_{y} includes a line width L₂ₓ(x) (the fourth line width) that changes in the x direction. (x) indicates that the line width is a function of the position x.

In the present embodiment, to correct the reduction of the exposure dose in the combined exposure region R_{C}, there is a correlation that L_{2y}(x)>L_{1y} and L₂ₓ(x)>L₁ₓ.

The specific changes of L_{2y}(x) and L₂ₓ(x) will be described after the exposure apparatus in which the photomask 1 is used is described.

A description will now be given of the exposure apparatus in which the photomask 1 is used as the exposure mask.

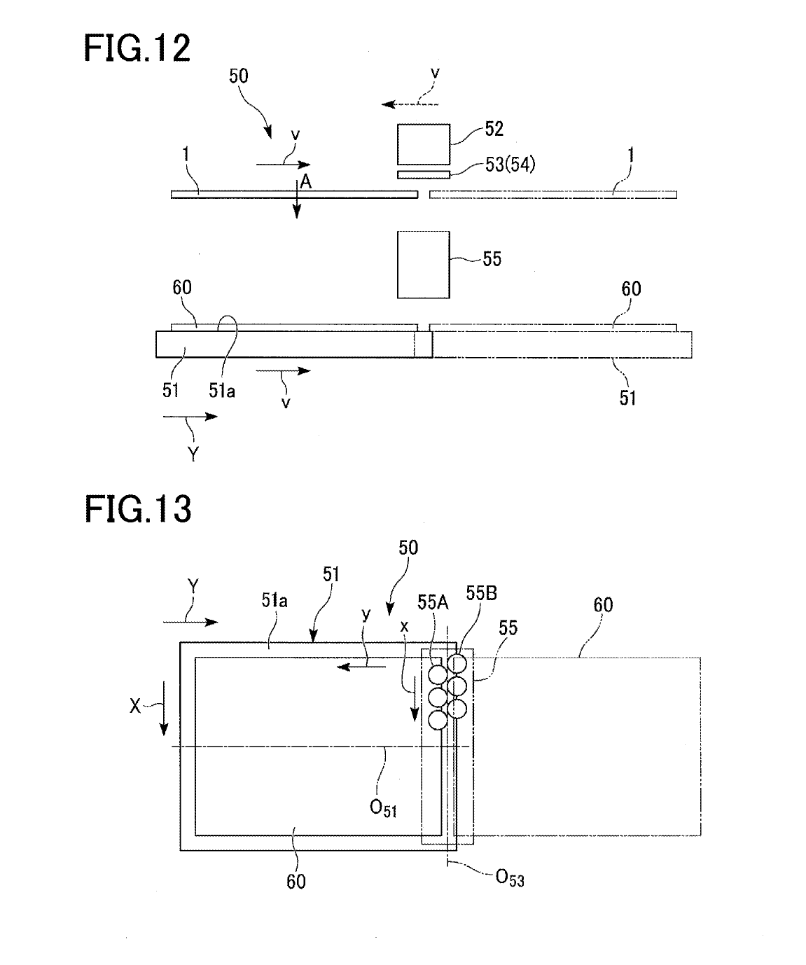

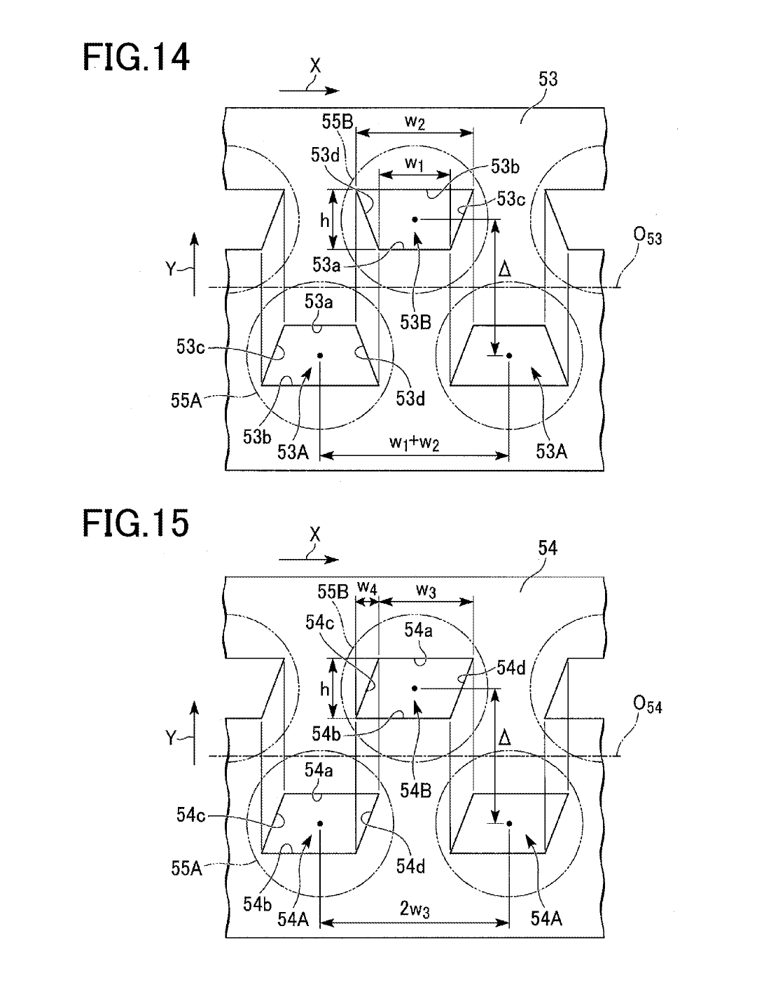

FIG. 12 is a schematic front view showing an example of an exposure apparatus in which the photomask according to the second embodiment of the present invention is used. FIG. 13 is a schematic plan view showing an example of an exposure apparatus in which the photomask according to the second embodiment of the present invention is used, and is a plan view as viewed from A in FIG. 12. FIG. 14 is a schematic plan view showing an example of a field stop used in the exposure apparatus. FIG. 15 is a schematic plan view showing another example of the field stop used in the exposure apparatus.

As shown in FIGS. 12 and 13, an exposure apparatus 50 includes a base 51, the photomask 1 of the present embodiment, an illumination light source 52, a field stop 53, and a projection optical unit 55.

The base 51 includes a flat upper surface 51a that is parallel to the horizontal surface. This is for mounting the exposure object 60 thereon. The base 51 is configured to be able to move by a driving apparatus (not shown, not shown hereinafter) in a direction along an axis O₅₁ (a second axis) which extends in the Y direction in the drawing (the direction from the left to the right in the drawing), of the horizontal directions. As shown by the dash-dot-dot line in the drawings, the driving apparatus can move the base 51 to a movement limit in the Y direction, and then can move the base 51 to a direction opposite to the Y direction to return to a movement starting position.

The base 51 may be configured to be able to move in the X direction orthogonal to the Y direction in the horizontal surface (move depth-wise in the drawing, i.e., move frontward as viewed perpendicular to FIG. 12) by a not-shown driving apparatus.

Using the exposure apparatus 50, the exposure object 60 is exposed to the exposure pattern which is based on the optical images of the mask pattern P of the photomask 1. As shown in FIG. 13, the exposure object 60 is smaller in plan view than the upper surface 51a, and is formed in a rectangular plate shape having a size equal to or smaller than that of the photomask 1. The exposure object 60 is placed on the upper surface 51a so that the longitudinal direction thereof is along the Y direction.

The exposure object 60 is configured by applying a photosensitive resist on an appropriate substrate to perform photolithography. This resist may be a negative resist or a positive resist.

In the exposure apparatus 50, the photomask 1 is arranged at a position facing the exposure object 60 placed on the base 51. The photomask 1 has a support part (not shown) which can be moved synchronously with the base 51 while maintaining a constant distance from the upper surface 51a of the base 51.

The photomask 1 of the exposure apparatus 50 is arranged such that the positive direction of the y-coordinate axis is opposite to the Y direction and the x-coordinate axis is along the X direction.

To expose the exposure object 60, the illumination light source 52 generates illumination light having a wavelength for sensitizing the resist on the exposure object 60. The illumination light source 52 is fixed and supported by a supporting member (not shown) above the moving region of the photomask 1. The illumination light source 52 irradiates the illumination light vertically downward.

The field stop 53 is arranged between the illumination light source 52 and the moving region of the photomask 1. The field stop 53 is fixed and supported by a supporting member (not shown). The field stop 53 shapes the illumination light irradiated by the illumination light source 52, and divides the illumination light into a plurality of illumination regions.

As shown in FIG. 14, the field stop 53 includes a plurality of first openings 53A arranged at a pitch of w₁+w₂ (w₁<w₂) in the X direction, and a plurality of second openings 53B arranged at a pitch of w₁+w₂ in the X direction on axes shifted parallel to each other by a distance Δ in the Y direction (details of Δ>h/2, and h will be described later).

The shape of the first openings 53A in plan view is an isosceles trapezoid in which the apex angle thereof is not a right angle. The first openings 53A are composed of first sides 53a, second sides 53b, third sides 53c, and fourth sides 53d.

The first side 53a is the upper base of the isosceles trapezoid, and the second side 53b is the lower base of the isosceles trapezoid. The lengths of the first side 53a and the second side 53b are w₁ and w₂, respectively. The first side 53a and the second side 53b are parallel lines separated by a distance h in the Y direction (hereinafter, the distance h may be referred to as opening width h). The third side 53c and the fourth side 53d are isosceles trapezoidal legs arranged in this order in the X direction. In the first openings 53A, the interval between the third side 53c and the fourth side 53d gradually becomes smaller in the Y direction.

The plan view shape of the second openings 53B is obtained by rotating the first openings 53A by 180° in plan view. That is, the second openings 53B are also composed of first sides 53a, second sides 53b, third sides 53c, and fourth sides 53d. The interval between the third sides 53c and the fourth sides 53d in the second openings 53B gradually becomes smaller in the Y direction. The positions of the second openings 53B in the X direction deviate from the first openings 53A by (w₁+w₂)/2. Therefore, the second openings 53B are arranged at positions opposed to the intermediate point between two first openings 53A in the Y direction.

With such arrangement, the first openings 53A and the second openings 53B are staggered along the axis O₅₃ (a first axis, X direction) in the X direction.

When viewed from the Y direction, in the first openings 53A and the second openings 53B, the third sides 53c of the two openings overlap each other, and the fourth sides 53d of the two openings overlap each other. When viewed from the Y direction, end parts of the first sides 53a (or the seconds sides 53b) of the first openings 53A and those of the second sides 53b (or the first sides 53a) of the second openings 53B are at the same position.

The shape, size and arrangement of the first openings 53A and the second openings 53B in the field stop 53 may be appropriately adjusted according to the arrangement and the like of the projection optical unit 55 described later. Specific dimension examples relating to the first openings 53A and the second openings 53B will be described below.

(w2−w1)/2 may be, for example, 14 mm or more and 18 mm or less. h may be, for example, 25 mm or more and 45 mm or less. (w₁+w₂)/2 may be, for example, 95 mm or more and 100 mm or less. The distance Δ may be, for example, 200 mm or more and 300 mm or less.

The field stop 53 of the exposure apparatus 50 may be replaced with, for example, a field stop 54 as shown in FIG. 15.

The field stop 54 includes a plurality of first openings 54A arranged at a pitch of 2w₃ in the X direction, and a plurality of second openings 54B arranged at a pitch of 2W₂ in the X direction. The second openings 54B are arranged on an axis which is shifted in parallel from the first openings 54A by the distance Δ in the Y direction.

The shape of the first openings 54A in plan view is a parallelogram whose vertex angles are not right angles. The first openings 54A are composed of first sides 54a, second sides 54b, third sides 54c, and fourth sides 54d. The first sides 54a and the second sides 54b are opposite sides in the Y direction. The third side 54c and the fourth side 54d are opposite sides in the X direction. Each length of the first sides 53a and the second sides 53b is w₃. The angle between the second side 54b and the third side 54c (i.e., the angle between the first sides 54a and the fourth sides 54d) is an acute angle. Let us assume this angle is θ, then each length of the third side 53c and the fourth side 53d is multiplied by cos θ to obtain w₄ (w₄<w₃).

The shape of the second openings 54B in plan view is the same as that of the first openings 54A. The position of the second openings 54B in the X direction deviates from the first openings 54A by w₃. Therefore, the second openings 54B are arranged at positions opposed to the intermediate point between two first openings 54A in the Y direction.

With such arrangement, the first openings 54A and the second openings 54B are staggered along the axis O₅₄ (a first axis) in the X direction.

When viewed from the Y direction, the third sides 54c of the first openings 54A and the fourth sides 54d of the second openings 54B overlap each other, and the fourth sides 54d of the first openings 54A and the third sides 54c of the second openings 54B overlap each other. When viewed from the Y direction, end parts of the first side 54a (or the second side 54b) of the first openings 54A and those of the first side 54a (or the second side 54b) of the second openings 54B are at the same positions.

As shown in FIG. 12, the projection optical unit 55 is arranged above the exposure object 60 on the base 51 so as to face the field stop 53 (54) with the moving region of the photomask 1 interposed therebetween. The projection optical unit 55 is fixed and supported by a supporting member (not shown).

As shown in FIG. 13, the projection optical unit 55 includes a plurality of first projection optical systems 55A (projection optical systems), and a plurality of second projection optical systems 55B (projection optical systems), which are staggered along the axis O₅₃.

Both the first projection optical systems 55A and the second projection optical systems 55B are imaging optical systems that form an object image as an erect equal-magnification image on the image plane. Each of the first projection optical systems 55A and the second projection optical systems 55B is arranged at a position where the mask pattern P of the photomask 1 and the upper surface of the resist-applied exposure object 60 are in a conjugate relationship with each other.

As shown in FIG. 14, the first projection optical systems 55A are arranged below the first openings 53A so that the image of the first openings 53A can be projected onto the exposure object 60. The second projection optical systems 55B are arranged below the second openings 53B so that the image of the second openings 53B can be projected onto the exposure object 60.

Due to the first projection optical systems 55A and the second projection optical systems 55B being arranged in such a positional relationship, a certain distance between the first openings 53A and the second openings 53B needs to be maintained so that the first projection optical systems 55A and the second projection optical systems 55B do not interfere with each other. Therefore, the distance Δ in the y direction between the first openings 53A and the second openings 53B is a large value such as a value of about 6 to 8 times larger than that of the opening width h in the Y direction.

As shown in FIG. 15, if the field stop 54 is used in place of the field stop 53, the first projection optical systems 55A are arranged below the first openings 54A so that the image of the first openings 54A can be projected onto the exposure object 60. The second projection optical systems 55B are arranged below the second openings 54B so that the image of the second openings 54B can be projected onto the exposure object 60.

A description will be given of an exposure operation performed by the exposure apparatus 50.

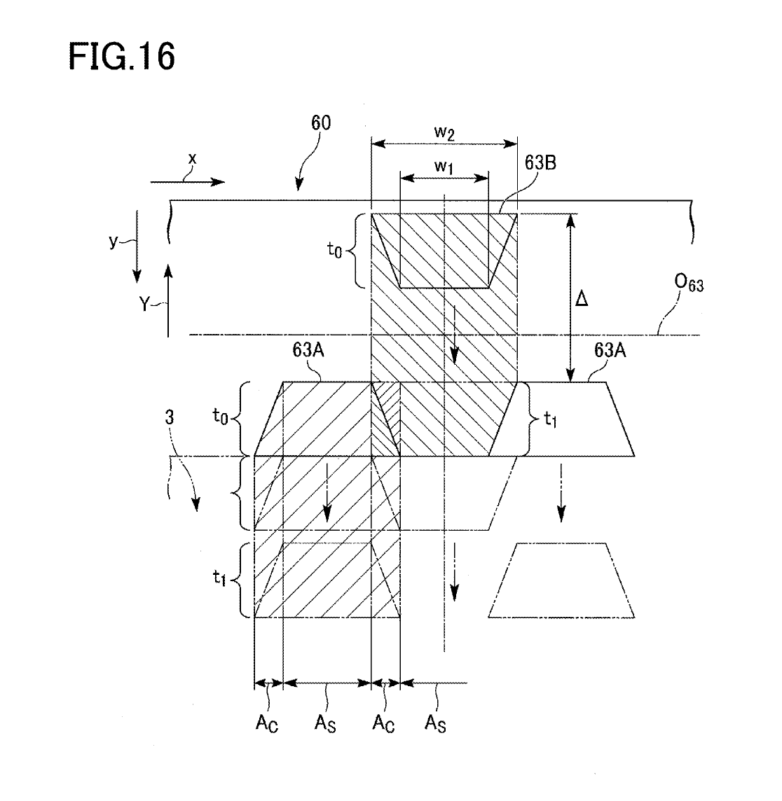

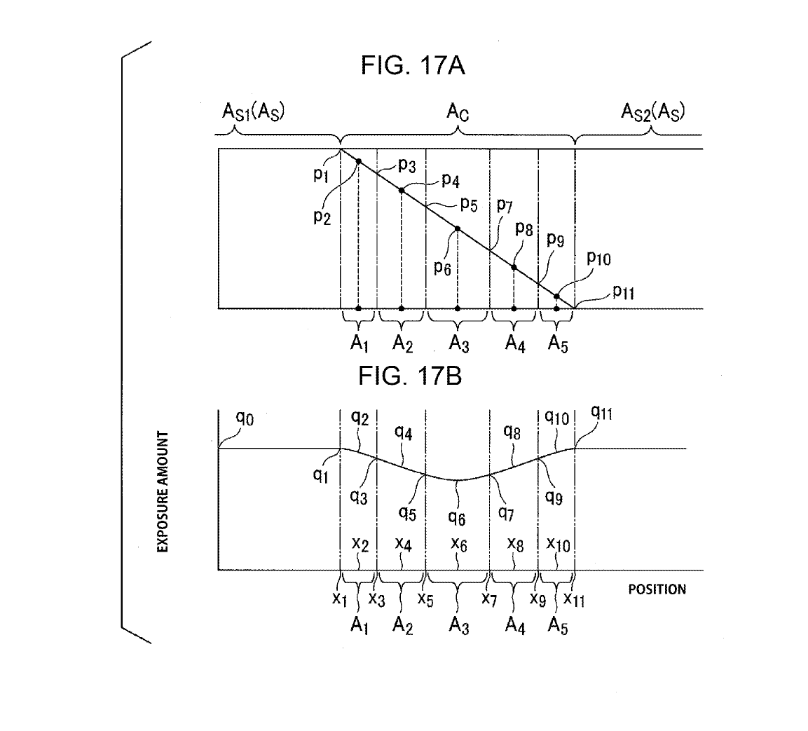

FIG. 16 is a schematic diagram describing the exposure operation performed by the exposure apparatus. FIGS. 17A and 17B are schematic diagrams describing an effective exposure dose in the exposure apparatus. In the graph shown in FIG. 17B, the lateral axis represents a position in the x direction, and the vertical axis represents the effective exposure dose described later.

FIG. 16 shows an enlarged view of a part of the tip end part in the exposure object 60 arranged below the projection optical unit 55. Although not shown in FIG. 16, in the position between the field stop 53 and the projection optical unit 55, the photomask 1 is moved so as to face the exposure object 60.

If the illumination light source 52 is lit, the illumination light transmitted through each of the first openings 53A of the field stop 53 and each of the second openings 53B of the field stop 53 irradiates the photomask 1.

Of the light transmitted through the light transmitting part 3a of the photomask 1, the light having passed the first openings 53A is through the first projection optical systems 55A, projected onto the exposure object 60 without magnification, and the light having passed the second openings 53B is through the second projection optical systems 55B, projected onto the exposure object 60 without magnification.

As a result, as shown in FIG. 16, on the exposure object 60, first optical images 63A, which are optical images of the light passing through the first openings 53A, and second optical images 63B, which are optical images of the light passing through the second openings 53B, are projected. In the first optical images 63A and the second optical images 63B, a luminance distribution is formed which corresponds to object images such as the mask pattern P. However, in FIG. 16, for simplicity, a drawing of the luminance distribution is omitted.

Similar to the first openings 53A and the second openings 53B, the first optical images 63A and the second optical images 63B are staggered along the axis O₆₃ which is parallel to the x coordinate axis, on the exposure object 60.

When the base 51 moves in the Y direction, each of the first optical images 63A and each of the second optical images 63B sweep the band regions of the width w₂ as indicated by the oblique lines in the drawing. Therefore, each of the first optical images 63A and each of the second optical images 63B are scanned over the exposure object 60 in the y direction.

However, the first openings 53A deviates from the second openings 53B by the distance Δ in the Y direction. Therefore, the regions where the first optical images 63A and the second optical images 63B are swept simultaneously are shifted by the distance (w₁+w₂)/2 in the x direction, and are shifted by the distance Δ in the y direction.

Let us assume that the moving speed of the base 51 is v. In this case, first, the first optical images 63A scans the band regions. Then, with the time difference T=A/v, the second optical images 63B reaches the other regions which is the same position as the regions swept by the first optical images 63A in the y direction.

For example, if scanning is started at time to, the second optical images 63B reach the positions where the first optical images 63A is positioned at time to in the y direction at time t₁=t₀+T. At this time, the second optical images 63B are fitted between the first optical images 63A which are adjacent to each other in the x direction and are formed at time to.

That is, at the time to, the region in the x direction where the first optical images 63A are arranged only are exposed by the first optical images 63A with a spacing in between, however, at the time t1, the unexposed parts of the region are exposed by the second optical images 63B. As a result, with time difference T, the regions extending in the x direction are exposed with no gap in the band shape. The legs of the isosceles trapezoidal shapes of the first light image 63A and the legs of the isosceles trapezoidal shapes of the second optical images 63B themselves are the joint of each exposure region.

In plan view, at the time t₀, the mask part 3 of the photomask 1 is at a position that is on a side opposite to the second sides 53b of the first openings 53A with reference to the y direction. As an example, FIG. 16 shows the tip end of the mask part 3 in the y direction is at the same position as the second sides 53b of the first openings 53A, at time t₀. Therefore, at the time to, the lower base of the isosceles trapezoid of the first optical images 63A is located at the tip end of the mask part 3.

In the regions where the first optical images 63A sweep by scanning, after time t₀, the mask pattern P of the photomask 1 is formed on the exposure object 60 by scanning. The exposure time of the mask pattern P is a time obtained by dividing the opening width h in the Y direction of the first openings 53A by the velocity v. In the rectangular shaped regions positioned between the first sides 53a and the second sides 53b of the first openings 53A, the exposure time t_{f} is h/v. Hereinafter, the exposure time t_{f} is referred to as full exposure time.

However, in the triangular regions positioned between the third sides 53c and the second sides 53b of the first openings 53A, and in the triangular regions positioned between the fourth sides 53d and the second sides 53b, the exposure time in the x direction changes linearly between 0 and full exposure time.

Similarly, in the regions where the second optical images 63B sweep by scanning, exposure similarly to that by the first optical images 63A is performed with a time difference T. Therefore, the regions swept by the second optical images 63B are divided into regions exposed at the full exposure time t_{f} and regions exposed with less than the full exposure time t_{f}.

The regions exposed with less than the full exposure time t_{f} are exposure regions related to the joint between the first optical images 63A at the time to and the second optical images 63B at the time t₁.

In the present embodiment, the regions to be exposed at the full exposure time t_{f} by the first optical images 63A and by the second optical images 63B are separated from each other, and each of them composes band shaped single exposure regions A_{S} extending in the y direction with each having a width w₁.

The width (width in the x direction) between adjacent single exposure regions A_{S} is indicated by (w₂−w₁)/2. These regions configure combined exposure regions A_{C} which are exposed by the first optical images 63A with a time less than the full exposure time t_{f} and are exposed by the second optical images 63B with a time less than the full exposure time t_{f}.

The exposure time at each position of the x direction in the combined exposure regions A_{C} is equal: the exposure potion between the first optical images 63A and the second optical images 63B is different, but the total exposure time is equal if combined.

Therefore, the exposure dose in the single exposure regions A_{S} and the exposure dose in the combined exposure regions A_{C} are equal as long as the illumination light intensities in the first optical images 63A and the second optical images 63B are the same.

Let us assume a case in which positive resist is, for example, applied to the exposure object 60. According to observations made by the inventors of the present invention, in such a case, the line width of the light transmitting part (the part the surface of the exposure object 60 is exposed) after being developed and being etched tends to be slightly thinner in the exposure pattern formed in the combined exposure regions A_{C}, compared with the exposure pattern formed in the single exposure regions A_{S} on the exposure object 60.

Because the combined exposure regions A_{C} extend in the y direction at a constant width and are formed at an equal pitch in the x direction, a change in the line width is easily recognized as a band shaped unevenness in density in the exposure pattern.

For example, when a photomask for BM is formed by the exposure apparatus 50, the sizes of the openings of the sub pixels are not uniform. This is why a liquid-crystal device in which regular color unevenness is visually recognized may easily be formed.

The reason why the line widths in the two regions are different from each other even though the same exposure time is applied, is not clear, however, the time difference T may be an influence.

If resist (positive resist) is exposed, the photochemical reaction is proceeded. Then, the resist can be removed by a developing solution. However, in the photochemical reaction of the resist, it takes some time for the reaction to start. If the exposure is interrupted, the reaction stops rapidly, and the photochemical reaction that has started is returned to the initial state.

As a result, because the intermittent exposure has shorter effective exposure time than the continuous exposure, the intermittent exposure may cause a similar effect to the case of the exposure dose being decreased.

Therefore, in the regions for combined exposure R_{C}, the effective exposure dose used for the net exposure of the resist may be determined by the ratio of the exposure time between the first optical images 63A and the second optical images 63B, if the light amount is the same.

As schematically shown in FIG. 17A, for example, in combined exposure regions A_{C} positioned between a single exposure region A_{S1} scanned by the first optical images 63A and a single exposure region A_{S2} scanned by the second optical images 63B, the exposure time scanned by the first optical images 63A and the exposure time scanned by the second optical images 63B change linearly along the x direction.

For example, the position indicated by the point p₁ is the boundary position with the single exposure region A_{S1}. This means, at this position, the ratio of the exposure time scanned by the first optical images 63A with respect to the total exposure time is 100%, and the ratio of the exposure time scanned by the second optical images 63B is 0%.

When the ratio (%) of the exposure time at each point shown in FIG. 17A is expressed as pₙ [t_{A}, t_{B}]; for example, p₁ [100, 0], p₂ [90, 10], p₃ [80, 20], p₄ [70, 30], p₅ [60, 40], p₆ [50, 50], p₇ [40, 60], p₈ [30, 70], p₉ [20, 80], p₁₀ [20, 80], p₁₁ [0, 100]. In the following, the position coordinates of these points pₙ in the x direction are represented by xₙ (n=1, . . . , 11).

A downwardly convex V-shaped graph in FIG. 17B shows the effective exposure dose which affects the line width and the like (hereinafter, also referred to as exposure dose), in the combine exposure region A_{C}. The exposure doses q₁ and q₁₁ at the positions x₁ and x₁₁ are equal to the exposure dose q₀ in the single exposure region A_{S}, respectively. For example, the exposure dose q₆ at the position x₆ is lower than the exposure dose q₀ and is the minimum value of the exposure dose in the combined exposure regions A_{C}. The change rate of the exposure dose is smooth in the vicinity of the positions x₁ and x₁₁, and in the vicinity of the position x₆. This graph is symmetrical with respect to the vertical axis passing through position x₆.

The exposure dose in the combined exposure regions A_{C} is represented by a continuous function with the position coordinate in the x direction as an independent variable. However, simply, with a stepwise change, the exposure dose may be approximated.

For example, with the section Aₙ being between a position x₂ₙ₋₁ and the position X₂ₙ₊₁, each exposure dose in a section Aₙ may be approximated by the average exposure dose of the section Aₙ.

In the photomask 1 of the present embodiment, the pattern P₁ in the regions for single exposure R_{S} for exposing the regions for single exposure A_{S} and the pattern P₂ in the regions for combined exposure R_{C} for exposing the regions for combined exposure A_{C} are switched corresponding to such a difference of the effective exposure dose. Therefore, in the x direction, the width W_{S} of the regions for single exposure R_{S} is equal to the width w₁ of the regions for single exposure A_{S}. The width W_{C} of the regions for combined exposure R_{C} is equal to the width (w₂−w₁)/2 of the regions for combined exposure A_{C}.

The pattern P₁ of the photomask 1 is formed in the same shape as the exposure pattern on the exposure object 60.

The pattern P₂ of the photomask 1 is corrected to a shape in which the exposure dose in the combined exposure regions A_{C} is corrected to be effectively equal to the exposure dose in the single exposure regions A_{S}. More specifically, the line width of the light transmitting part 3a in the regions for combined exposure R_{C} vary with the coordinate x, such as L_{2y} (x) and L₂ₓ (x).

For example, at x=x₁, and x=x₁₁ which corresponds to the above-described points p₁, and p₁₁, L_{2y} (x)=L_{1y}, and L₂ₓ (x)=L₁ₓ. For example, at x=x₆ which corresponds to the above-described point p₆, L_{2y} (x)=L_{ymin}, and L₂ₓ(x)=Lₓₘᵢₙ. L_{ymin} (or Lₓₘᵢₙ) is the minimum value of the line width in the y direction (or x direction), and is smaller than L_{1y} (or L₁ₓ).

A description will now be given of a method for producing a photomask of the present embodiment.

In the method for producing the photomask of the present embodiment, the photomask 1 is produced by photolithography using a scanning beam as an exposure means.

Depending on the scanning beam, the drawing pattern of the photomask 1 itself may be changed to change the shape of the light transmitting part 3a. However, this method needs to use a scanning beam capable of high-resolution drawing, because the amount of change in the shape of the light transmitting part 3a is very small. A beam scanning device that forms such a scanning beam needs to have enhanced optical performance. This means that the size of the device may be increased and the scanning range may become narrower.

Particularly if the outer shape of the photomask 1 is large, a large beam scanning device is required to secure necessary scanning widths. This means, the equipment cost and production cost may be increased.

Beam scanning may be performed by dividing a scanning region into a plurality of regions by using a small beam scanning device having high optical performance. However, if performed by this method, a pattern connection error may easily occur in the connecting portions of the scanning regions.

In the present embodiment, by modulating the intensity of the scanning beam without changing the drawing pattern, a corrected shape is formed only in the regions for combined exposure R_{C}.

First, a description will be given of the intensity modulation of this scanning beam.

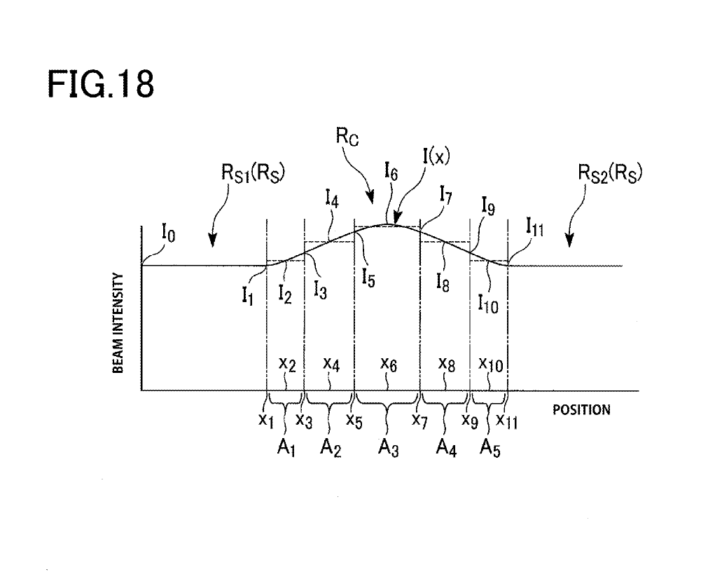

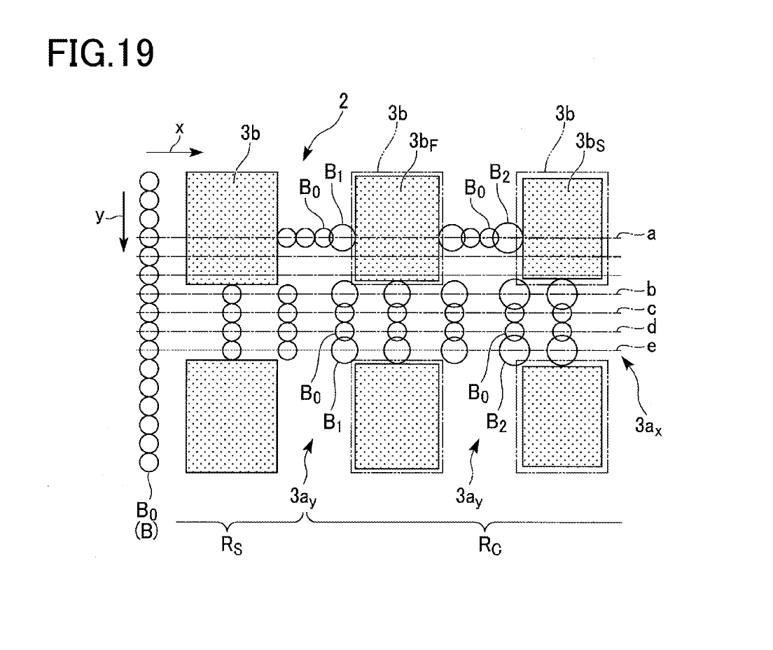

FIG. 18 is a schematic graph for describing an example of the beam intensity of the scanning beam used in the method for producing the photomask according to the second embodiment of the present invention. In FIG. 18, the horizontal axis indicates the position in the x direction, and the vertical axis indicates the beam intensity. FIG. 19 is a schematic diagram for describing a method of setting beam intensity data, in the method for producing the photomask according to the second embodiment of the present invention.

In the present embodiment, to correct the variation of the effective exposure dose represented by the graph of FIG. 17B, the beam intensity of the scanning beam for producing the photomask 1 is controlled based on the graph shown in FIG. 18. In the present embodiment, to produce the photomask 1, a positive resist is applied to the surface of the light transmitting substrate 2. Therefore, the beam intensity shown in FIG. 18 is also set so as to be suited for the exposure of the positive resist applied to the light transmitting substrate 2.

The positions x₁ to x₁₁ at the horizontal axis in FIG. 18 indicate positions in the combined exposure regions R_{C} which correspond to the combined exposure region A_{C} in FIG. 17B. The left side of the position x₁ and the right side of the position x₁₁ in the figure respectively represent the regions for single exposure R_{S1} and R_{S2} which correspond to the regions for single exposure A_{S1} and A_{S2} in FIG. 17A.

As shown in FIG. 18, the beam intensity of the scanning beam is shown by the upwardly convex shaped (inverted V shape) graph in the combined exposure region R_{C}. The position x₁ (or x₁₁) is a boundary point between the single exposure region R_{S1} (or R_{S2}) and the combined exposure region R_{C}. This is why, the respective beam intensities I₁=I(x₁), and I₁₁=I (x₁) are equal to the beam intensity I₀ in the single exposure region R_{S}.

For example, the beam intensity I₆=I(x₆) at the position x₆ is higher than the beam intensity I₀, and is the maximum value of the beam intensity in the combined exposure region R_{C}. The change rate of the beam intensity I(x) in the vicinity of the positions x₁ and x₁₁, and in the vicinity of the position x₆ varies smoothly.

This graph is symmetrical with respect to the vertical axis passing through position x₆.

The beam intensity I(x) in the combined exposure region R_{C} is represented by the curved continuous function with the position coordinate in the x direction as an independent variable. The specific functional type of I(x) is determined, for example, by obtaining the necessary line width correction amount in the combined exposure regions A_{C} by performing experiment or the like. The beam intensity for realizing the line width correction amount can be obtained by numerical simulation or experiment according to the relationship between the beam intensity and the line width under the conditions of the producing process of the photomask 1.

The beam intensity I(x) may be simply approximated by a stepwise function.

For example, each beam intensity within the section Aₙ may be approximated by the average beam intensity in the section Aₙ (see the dashed lines in the drawing).

The beam intensity I(x) can also be expressed as a function of the parameter λ based on the following equation (1), such as I=f(λ).

$$\begin{matrix}[ Equation 2 ] & \\ λ = \frac{\vert E 1 - E 2 \vert}{E 1 + E 2} & ( 1 )\end{matrix}$$

E1 refers to the exposure ratio scanned by the first optical images 63A, and E2 refers to the exposure ratio scanned by the second optical images 63B. The exposure ratio is the ratio of the exposure dose of a specific light source (for example, the illumination light passing through the first opening 53A or the illumination light passing through the second opening 53B) with respect to the entire exposure dose, at a specific position.

Because such an exposure ratio is a function of x, the parameter λ is also a function of x. For example, at position x1 (or x11), λ=1 because E1=1, and E2=0 (or E1=0, and E2=1), and at position x 6, λ=0 because E1=0.5, and E2=0.5.

f(λ) takes a maximum value at λ=0, and f(λ) approaches I₀ as λ changes from 0 to 1. f(λ) is a weakly decreasing function.

As a specific method of setting the beam intensity, the beam intensities of all the scanning beams that scan the combined exposure region R_{C} may be set based on the graph in FIG. 18 (hereinafter referred to as uniform setting method). In this case, there are portion that do not affect the line width of the light transmitting part 3a even if the beam intensity is changed, such as, the central part of the line width of the light transmitting part 3a. If the portions are positioned in the regions for combined exposure R_{c}, the beam intensity is increased.

By comparison, based on the graph shown in FIG. 18, the beam intensity may be set by selecting portions affecting the line width of the light transmitting part 3a in the regions for combined exposure R_{C} (hereinafter referred to as selection setting method). Specifically, there are positions in the regions for combined exposure R_{c}, in which the scanning beam is turned on, adjacent to the scanning positions in which the scanning beam is turned off (hereinafter referred to as edge scanning position). At least the beam intensity in those positions are set based on FIG. 18.

FIG. 19 schematically shows an example of the beam intensity setting using the selection setting method.

The scanning beam B raster-scans the light transmitting substrate 2 with the x direction as the main scanning direction. In the single exposure region R_{S}, the scanning beam B₀ which is set to the beam intensity I₀ (first beam intensity) is used as the scanning beam B.

In the regions for single exposure R_{S}, the light shielding parts 3b are formed in a rectangular shape having a size corresponding to the exposure pattern of the exposure object 60. In the present embodiment, the regions for combined exposure R_{C} form the light shielding parts 3b_{F}, and ‘3b_{S}, that are gradually reduced in size toward the center in the x direction of the combined exposure region R_{C}. Therefore, the scanning beams B₁ and B₂ at the edge scanning positions of the light shielding parts 3b_{F} and 3b_{S} are set to beam intensity I_{F} and I_{S} (second beam intensity) larger than the beam intensity I₀. Note that I_{F}<I_{S}.

For example, the scanning beam B scans the light transmitting substrate 2 on the scanning line a, in the order of B₀, B₀, B₀, B₁ between the light shielding parts 3b, and 3b′. On the light shielding parts 3b′, the scanning beam B is turned off. Between the light shielding parts 3b_{F} and 3b_{S}, the scanning beam B scans the light transmitting substrate 2 in the order of B₁, B₀, B₀, B₂.

The scanning beam B that scans along the scanning lines b and e that pass through the edge scanning positions of the light shielding parts 3b, 3b_{F} and 3b_{S} is taken to be scanning beams B₁ and B₂ at positions passing through the edge scanning positions of the light shielding parts 3b_{F} and 3b_{S}. Otherwise, the scanning beam B is taken to be scanning beam B₀.

In the scanning lines c and d which do not pass through the edge scanning positions of the light shielding parts 3b_{F} and 3b_{S}, all scanning beam B is taken to be the scanning beam B₀.

In the regions for combined exposure R_{C}, the beam intensity of the scanning beam B₀ that scans positions other than the edge scanning positions is I₀. This beam intensity may be set to the third beam intensity I_{T}. The beam intensity I_{T} is set to a value of I₀ or more and I_{S} or less. That is, the beam intensity I_{T} is set to be equal to or less than the maximum value of the second beam intensity in the combined exposure region R_{C}.

A description will now be given of steps of the method for producing the photomask of the present embodiment.

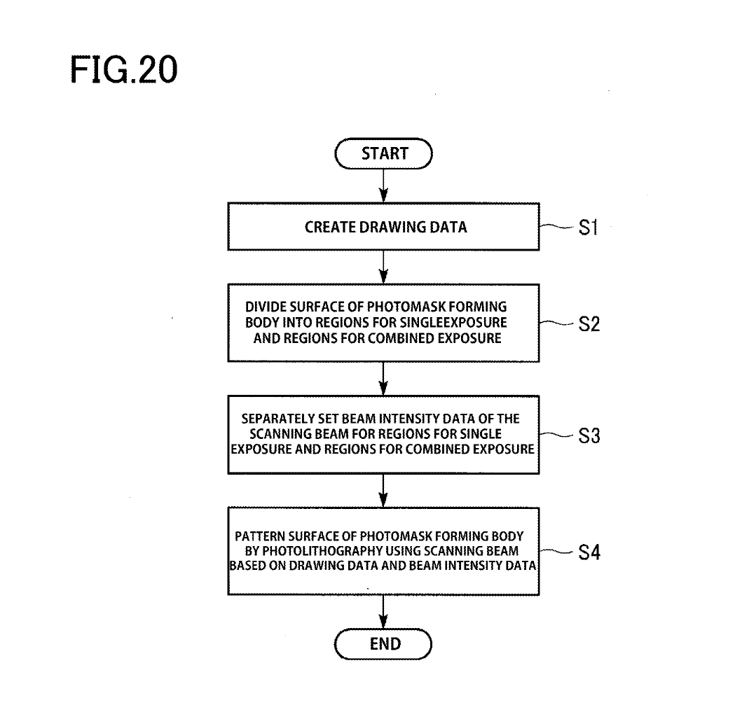

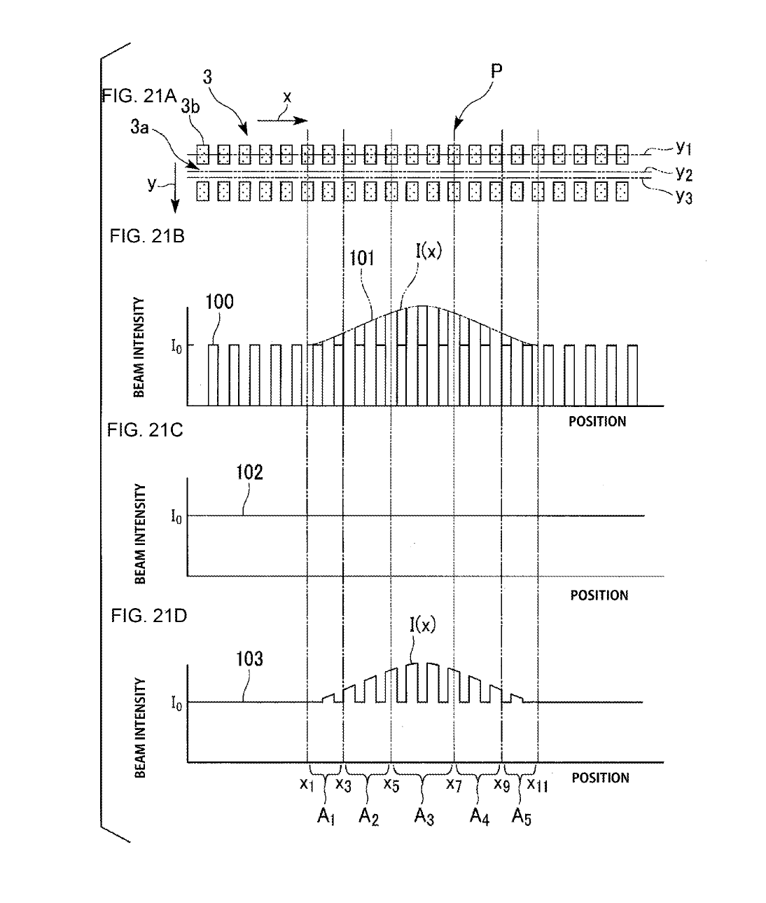

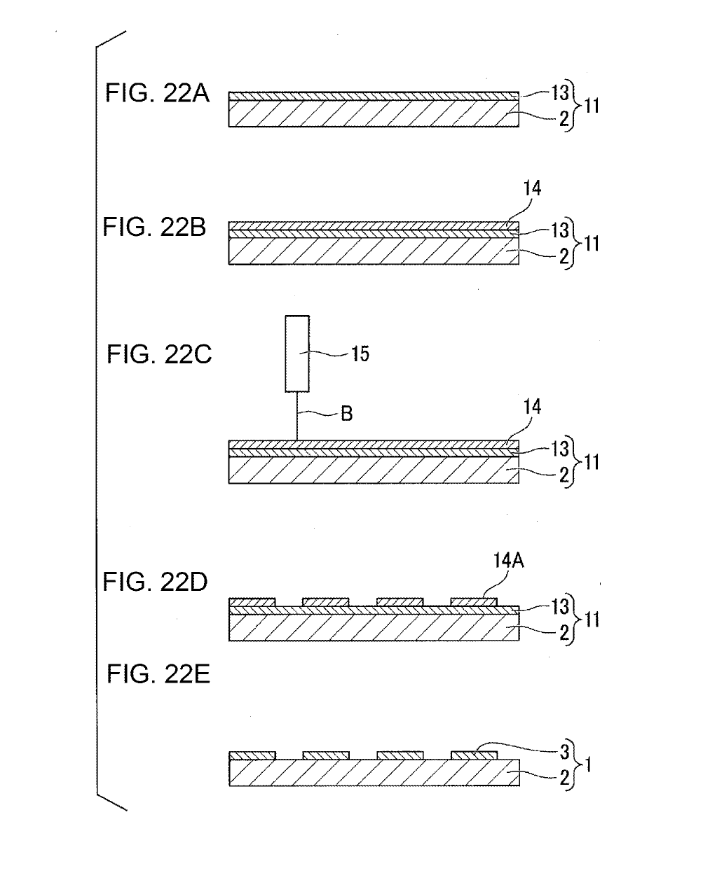

FIG. 20 is a flowchart showing an example of the method for producing the photomask according to the second embodiment of the present invention. FIGS. 21A, 21B, 21C, and 21D are schematic diagrams for describing setting examples of beam intensity data in the method for producing the photomask according to the second embodiment of the present invention. FIGS. 22A, 22B, 22C, 22D, and 22E are process explanatory diagrams of the method for producing the photomask according to the second embodiment of the present invention.

In the method for producing the photomask of the present embodiment, to produce the photomask 1, steps S1 to S4 shown in FIG. 20 are executed according to the flow shown in FIG. 20.

The following steps S1 to S3 are executed automatically, or interactively which is based on operation inputted by an operator, by using a data processing device in which an arithmetic processing program for performing the following operation is incorporated. Step S4 is executed by a system for producing the photomask including, for example, a beam scanning device, a developing device, and an etching device.

At step S1, drawing data of the mask pattern P for producing the photomask 1 is created. The drawing data is used to turn on and turn of the scanning beam to form the mask pattern P. The drawing data is generated, for example, by converting the position coordinates of the light transmitting part 3a and the light shielding parts 3b in the CAD design data of the mask pattern P into driving data corresponding to the beam scanning device which emits the scanning beam.

Then step S1 is terminated.

After step S1, control proceeds to step S2. At step S2, the surface of the photomask-forming body is divided into regions for single exposure R_{S} and regions for combined exposure R_{C}.

In the data processing device, the shape of the photomask 1 and the positional relationship with the field stop 53 arranged in the exposure apparatus 50, and the shape and positional information of the first openings 53A and the second openings 53B in the field stop 53 are inputted beforehand or during step S2.

Based on these pieces of inputted information, and based on the coordinate system of the surface of the photomask-forming body for forming the photomask 1, the data processing device generates information for classifying the regions for single exposure R_{S} from the regions for combined exposure R_{C}.

Then step S2 is terminated.

After step S2, control proceeds to step S3. At step S3, the beam intensity data of the scanning beam is set for each of the regions for single exposure R_{S} and the regions for combined exposure R_{C}. In the following, a description will be given of the case if the above-described selection setting method is used.

In the data processing device, the beam intensity for forming the pattern P₁ of a single exposure region R_{S}, and the beam intensity at the edge scanning positions for forming the pattern P₂ of a combined exposure region R_{C} are inputted beforehand or during execution of step S3.

Based on these pieces of inputted information, for example, the data processing device sets the above-described I₀ for the beam intensity in the regions for single exposure R_{S}.

The data processing device analyzes the drawing data of the regions for combined exposure R_{C} and extracts the edge scanning positions. The data processing device sets the beam intensity I(x) (second beam intensity) corresponding to the x coordinate at an edge scanning positions as the beam intensity at the edge scanning positions. The beam intensity I(x) may be stored in the data processing device, for example, as map data, or as a function. As a function, for example, the beam intensity I(x) may be maintained as a function such as I=f(λ).

Except for the edge scanning positions, the data processing device sets the beam intensity of the beam intensity data to the above-described I₀, in the regions for combined exposure R_{C}.

For example, FIGS. 21B, 21C, and 21D shows examples of beam intensity data in the mask pattern P shown in FIG. 21A. The vertical axes in FIGS. 21B, 21C, and 21D show the beam intensity of the scanning beam which is actually scanned. The beam intensity is composed by synthesizing the drawing data and the beam intensity data.

For example, as indicated by a scanning line y₁ of FIG. 21A, if a scanning line traverses where the formation position of the light shielding part 3b is traversed in the x direction, as indicated by a polygonal line 100 in FIG. 21B, the scanning beam is turned off on the light shielding parts 3b. On the light transmitting part 3a, the beam intensity is taken to be I₀ in the regions for single exposure R_{S} and the regions for combined exposure R_{C} excluding the edge scanning positions. At the edge scanning positions in the regions for combined exposure R_{C}, a beam intensity I(x) is set whose magnitude is variable. The beam intensity I(x) changes, drawing following a convex envelope curve 101 as viewed in the figure.

For example, as indicated by the scanning line y₂ of FIG. 21A, when a scanning line traverses between the forming positions, which are adjacent in the y direction, of the light transmitting part 3a, the beam intensity is set to I₀, as indicated by a straight line 102 of FIG. 21C.

For example, as indicated by the scanning line y₃ in FIG. 21A, when a scanning line passes through the edge scanning positions which are at positions in the x direction of the light shielding parts 3b, the beam intensity is set to I₀ in the regions for single exposure R_{S}, and in the regions for combined exposure R_{C}, as indicated by the curve 103 in FIG. 21D. The beam intensity is set to I(x) at the edge scanning positions of the regions for combined exposure R_{C}. In the scanning line y₃, because the edge scanning positions are at positions in the x direction, the curve 103 changes into a convex comb shape, as viewed in the figure.

After all the beam intensity data have been set, step S3 is terminated.

After step S3, control proceeds to step S4. At step S4, the surface of the mask forming body is patterned by lithography using the scanning beam based on the drawing data and the beam intensity data.

As shown in FIG. 22A, the photomask-forming body 11 is composed by laminating a light shielding layer 13 which is formed by a material composing the mask part 3, on the surface of the light transmitting substrate 2. As a method to laminate the light shielding layer 13, for example, vapor deposition, sputtering or the like may be used.

After the photomask-forming body 11 is formed, the resist 14 is coated on the light shielding layer 13 to pattern the light shielding layer 13.

With regard to the resist 14, an appropriate resist material (positive resist) is used that is sensitized by a scanning beam B described later.

After that, the photomask-forming body 11 coated with the resist 14 is carried into the photomask producing system.

As shown in FIG. 22C, the resist 14 is two-dimensionally scanned by the scanning beam B emitted from a beam scanning device 15 of the photomask producing system.

With respect to the scanning beam B, an appropriate energy beam is used for sensitizing the resist 14. For example, an energy beam such as a laser beam or an electron beam may be used as the scanning beam B.

Turning on and off of the scanning beam B, and the beam intensity when the scanning beam B is in an on state, is controlled by the beam scanning device 15, based on the drawing data and the beam intensity data, inputted to the beam scanning device 15.

In the resist 14, the irradiation range by the scanning beam B is sensitized. The range of exposure irradiated by the scanning beam B becomes larger as the beam intensity increases. Therefore, at the edge scanning positions where the beam intensity is set larger than I₀, the range of exposure becomes large according to the magnitude of the beam intensity.

If scanning of the entire photomask-forming body 11 is completed, the photomask-forming body 11 is developed by the developing device. As a result, as shown in FIG. 22D, the exposed resist 14 is removed from the light shielding layer 13. The resist 14 in the regions not irradiated by the scanning beam B is left as residual resists 14A.

Then, the residual resists 14A and the light shielding layer 13 which is exposed between the residual resists 14A are removed by an etching apparatus.

As shown in FIG. 22E, by such etching, the light shielding layer 13 is patterned to have the same shape as the residual resists 14A. As a result, the photomask 1 having the mask part 3 formed on the light transmitting substrate 2 is produced.

With the photomask 1 produced in this way, the shape of the mask part 3 in the regions for combined exposure R_{C} is corrected so that the light transmitting part 3a becomes wider than the exposure pattern. Therefore, if the photomask 1 is applied to the exposure apparatus 50, insufficiency of the effective exposure dose is corrected, which is due to the joint between the exposure regions of the first optical images 63A and the second optical images 63B, of the exposure apparatus 50. As a result, on the exposure object 60 which is exposed by the exposure apparatus 50 by using the photomask 1, insufficiency of the exposure dose is corrected in the regions for combined exposure R_{C}. Thus, accuracy in the exposure pattern shape is increased.

According to the method for producing the photomask of the present embodiment, the intensity of the scanning beam is modulated to produce the photomask 1 which corrects the production error due to the joint of the exposure regions of the exposure apparatus. Therefore, minute shape correction of the mask part 3 is performed easily and inexpensively in the regions for combined exposure R_{C}.

For example, apart from the present embodiment, there may be a production method in which the scanning beam turns on and off in a range of a correction shape, with the beam intensity of the scanning beam kept constant. However, in such a producing method, a high-resolution beam scanning device is required so that the correction region can be divided sufficiently finely to correct the minute shape difference. This is why, the equipment cost and the producing time may be increased.

By comparison, if intensity modulation of the scanning beam is used, the size of the exposure range can be finely changed by only setting the beam intensity data appropriately. Drawing data corresponding to a designed exposure pattern can be used regardless of the magnitude of the correction amount.

Therefore, in the present embodiment, by intensity modulation, a corrected shape can quickly and highly accurately be formed, while substantially the same scanning process is performed as in the case where the correction is not performed.

The description of the second embodiment has been provided by way of an example in which the light transmitting part 3a of the mask part 3 is composed of linear patterns of the rectangular lattice shape. However, the mask pattern P of the mask part 3 is not limited to such a linear pattern in which patterns in the scanning direction and the patterns orthogonal to the scanning direction are combined.

The shape of the mask pattern P can be changed according to the exposure pattern of the exposure object 60 as required. In this case, in the exposure pattern, the above-described line width may have an interval of the components of the scanning direction and the direction orthogonal to the scanning direction, for setting of beam intensity data.

The description of the second embodiment has been provided by way of an example in which the projection optical unit 55 exposes the entire width of the exposure object 60 in the X direction. However, if the exposure pattern of the exposure object 60 is only exposed by using a single photomask 1, the projection optical unit 55 may have a size covering a part of the projection optical unit 55 in the X direction. In this case, by performing the scanning exposure in the Y direction of the exposure apparatus 50 a plurality of times while being shifted in the X direction, the entire exposure object 60 is exposed.

In the second embodiment, the resist applied to the light transmitting substrate 2 in the producing process of the photomask 1 is a positive resist. However, the present invention is not limited to this configuration, and a negative resist may be applied to the light transmitting substrate 2. In this case, in order to produce the photomask 1 shown in FIG. 9 to FIG. 11, portions corresponding to the light shielding parts 3b are irradiated with a beam, and portions corresponding to the light transmitting parts 3a are not irradiated with a beam. In order to form the mask pattern shown in FIG. 11 using the negative resist, the beam intensity at the edge scanning positions of the regions for combined exposure R_{C} may be decreased than the beam intensity I₀ in the regions for single exposure R_{S}. At the edge scanning positions where the beam intensity is set to a value smaller than I₀, the range of exposure becomes smaller according to the magnitude of the beam intensity. In the regions for combined exposure R_{C}, the beam intensity of the scanning beam that scans other than at the edge scanning positions may be set to I₀.

If the beam intensity I(x) at the edge scan positions in this case is expressed as f₂ (λ), which is a function of the parameter k based on the above equation (1), f₂ (λ) takes a minimum value at λ=0, and becomes a weakly increasing function in which f₂(λ) approaches I₀ as λ changes from 0 to 1.

That is, in the present invention, the beam intensity at the edge scanning positions of the regions for combined exposure R_{C} may be different from the beam intensity in the regions for single exposure R_{S}.

In the second embodiment described above, the light transmitting part 3a of the photomask 1 has the shape extending in the x direction or the y direction, and the light shielding parts 3b have the rectangular shape in the plan view surrounded by the light transmitting part 3a. However, the present invention is not limited to this configuration, and the mask pattern of the photomask may, for example, be configured by reversing the positions of the light transmitting part and the light shielding parts of the photomask 1 of FIG. 9, according to the exposure pattern of the exposure object 60 and the type of resist (positive resist, and negative resist) applied to the exposure object 60. That is, the light shielding parts may have a shape extending in the x direction or the y direction, and the light transmitting part may have a rectangular shape in plan view surrounded by the light shielding parts. In such a configuration as well, if the resist applied to the light transmitting substrate of the photomask is a positive resist, the beam is irradiated onto part corresponding to the light transmitting part. If the resist applied to the light transmitting substrate of the photomask is a negative resist, the beam is irradiated onto parts corresponding to the light shielding parts.

In the second embodiment described above, by making the beam intensity at the edge scanning positions in the regions for combined exposure R_{C} to be higher than the beam intensity in the regions for single exposure R_{S}, the shape of the light transmitting part 3a is changed. However, the present invention is not limited to this configuration, and, for example, by changing the drawing pattern of the photomask 1, the shape of the light transmitting part 3a may be changed.

If the line width of the mask pattern in the regions for combined exposure R_{C} is made larger than the line width of the mask pattern in the regions for single exposure R_{S}, the line width may be set to gradually become larger closer to the center part of the regions for combined exposure R_{C} in the x direction. If the line width of the mask pattern in the regions for combined exposure R_{C} is made smaller than the line width of the mask pattern in the regions for single exposure R_{S}, the line width may be set to gradually become smaller closer to the center part of the regions for combined exposure R_{C} in the x direction. That is, the difference of the line width for the mask pattern between the regions for combined exposure R_{C} and the regions for single exposure R_{S} may be set to gradually become larger closer to the center part of the regions for combined exposure R_{C} in the x direction.

In the second embodiment described above, the x direction and the y direction are orthogonal to each other in plan view, but both directions may cross each other without being orthogonal in plan view. Also in this case, the y direction and the Y direction may be parallel with each other.

Each of the configurations of the first and second embodiments may be applied to a photomask and a method for producing a photomask. For example, the photomask of the first embodiment shown in FIGS. 5A, 5B, 5C, and 5D and FIGS. 6A, 6B, 6C, and 6D may be produced by using the method for producing the photomask described in the second embodiment.

Some preferred embodiments of the present invention have been described so far, but the present invention is not limited to the above-described embodiments. One or more constituents may be added, removed, or substituted, or other changes may be made without departing from the spirit of the present invention.

Furthermore, the present invention should not be limited by the foregoing description, but should be limited only by the appended claims.

### INDUSTRIAL APPLICABILITY

The photomask of the present invention and the method of producing the color filter using the photomask can be suitably used for producing the color liquid-crystal-display panel requiring high display quality, and the high-definition liquid-crystal display device using that the color liquid-crystal-display panel.

Furthermore, recently, even in producing a solid-state image sensor, the scanning exposure apparatus has tended to be used. Thus, the photomask of the present invention can also be suitably used for producing such a color filter and micro-lenses for a solid-state image sensor.

### REFERENCE SIGNS LIST

31 . . . Exposure light; 32 . . . Photomask; 33 . . . projection lens assembly; 34 . . . Substrate; 35 . . . Stage; 36 . . . Exposure region; 36a . . . Connecting portion; 37 . . . Light shielding region; 38 . . . Photomask having colored pixel pattern; 38a, 38b . . . Part of photomask having colored pixel pattern; 39 . . . Photomask having black matrix pattern; 39a . . . Part of photomask having black matrix pattern; CL1 . . . Characteristic curve according to measurement values; CL2 . . . Correction curve; SA1 . . . Scanning region not including connecting portions; SA2 . . . Scanning region including connecting portions; C3n . . . One colored pixel pattern.

1. A photomask used for scanning type projection exposure comprising a projection lens assembly composed of a lens assembly, a light transmitting substrate, and a mask pattern, wherein:
the mask pattern comprises a plurality of patterns that are two-dimensionally formed in a x direction along the long side of a light transmitting substrate and a y direction along the short side of the light transmitting substrate, and wherein a line width in the plurality of patterns of the photomask present in a region to be transferred by performing scanning exposure includes a plurality of connecting portions of the lens assembly are corrected with respect to a line width of patterns which are the same as the patterns of the photomask present in a region to be transferred by performing scanning exposure but do not include the connecting portions, wherein the line width of the transferred pattern is corrected by multiplying it with a correction coefficient determined by a correction curve, wherein the correction curve is determined by measuring line width changes in the scanning direction during transfer of the patterns.

2. The photomask of claim 1, wherein:
the corrected line width of the plurality of patterns changes stepwise in a direction orthogonal to a scanning direction for each of the patterns.

3. The photomask of claim 2, wherein:
the corrected line width of the plurality of patterns further changes stepwise in the scanning direction for each of the patterns.

4. The photomask of claim 2, wherein:
the line width that changes stepwise includes a correction component based on a random number.

5. A photomask on which a first light transmitting part linearly extending in a direction along a first coordinate axis in a plan view, and a second light transmitting part linearly extending in a direction along a second coordinate axis crossing the first coordinate axis in the plan view are formed, comprising:
first regions in a direction along the first coordinate axis, wherein the first light transmitting part has a constant first line width, and the second light transmitting part has a constant second line width; and
second regions in a direction along the first coordinate axis, wherein the first light transmitting part has a third line width which is wider than the first line width, and the second light transmitting part has a fourth line width wider than the second line width, wherein:
the first regions and the second regions are alternately arranged in the direction along the first coordinate axis.

6. A method for producing a photomask for forming optical images used in an exposure apparatus in which an exposure object is exposed, by using optical images obtained by a plurality of projection optical systems staggered along a first axis in plan view, and by scanning the exposure object in a direction along a second axis which intersects the first axis; including steps of:
setting a first coordinate axis corresponding to the first axis and a second coordinate axis corresponding to the second axis on a photomask-forming body, and creating drawing data for turning on and off a scanning beam on the photomask-forming body, according to a shape of an exposure pattern on the exposure object;
dividing the surface of the photomask-forming body into regions for single exposure where scanning in a direction along the second axis is performed by first optical images by a single first projection optical system or second optical images by a single second projection optical system of the plurality of projection optical systems in the exposure apparatus, and regions for combined exposure where scanning in a direction along the second axis is performed by the first and second optical images by the first and second projection optical systems;
separately setting beam intensity data of the scanning beam for the regions for single exposure and the regions for combined exposure;
applying a resist on the photomask-forming body; and
scanning the scanning beam that is driven based on the drawing data and the beam intensity data, onto the resist; wherein:
the beam intensity data is set to a first beam intensity in the regions for single exposure, and
the beam intensity data is set to a second beam intensity different from the first beam intensity at edge scanning positions, which are adjacent to scanning positions for turning off the scanning beam, to turn on the scanning beam, in the regions for combined exposure.

7. The method for producing the photomask of claim 6, wherein:
the second beam intensity is higher intensity than the first beam intensity.

8. The method for producing the photomask of claim 7, wherein:
the beam intensity data is set, at scanning positions other than the edge scanning positions, in the regions for combined exposure, to a third beam intensity which is not less than the first beam intensity and not more than the maximum value of the second beam intensity.

9. The method for producing the photomask of claim 8, wherein:
the third beam intensity is equal to the first beam intensity.

10. The method for producing the photomask of claim 1, wherein:
the second beam intensity is set as a function of λ expressed by the following equation (1) when an exposure ratio scanned by the first optical images is taken to be E1 and an exposure ratio scanned by the second optical images is taken to be E2, at the edge scanning positions.
$$\begin{matrix}[ Equation 1 ] & \\ λ = \frac{\vert E 1 - E 2 \vert}{E 1 + E 2} & ( 1 )\end{matrix}$$

11. The method for producing the photomask of claim 10, wherein:
the second beam intensity takes a maximum value at λ=0 and approaches the first beam intensity as λ changes from 0 to 1.

12. The method for producing the photomask of claim 6, wherein:
the second beam intensity is lower intensity than the first beam intensity.

13. The method for producing the photomask of claim 6, wherein:
the drawing data is set to turn on the scanning beam in a lattice-shaped region extending along the first coordinate axis and the second coordinate axis.

14. A method for producing a color filter by using a scanning type projection exposure that includes a projection lens assembly composed of a lens assembly, wherein:
a pattern exposure is performed on a resist provided on a glass substrate or a silicon substrate by using a photomask of claim 1.

15. The photomask of claim 1, wherein the line width is corrected in the x direction by multiplying it width the correction coefficient.

16. The photomask of claim 1, wherein the line width is corrected in the y direction by multiplying it width the correction coefficient.

17. The photomask of claim 1, wherein the mask pattern corresponding to one pixel is divided into n portions, wherein the correction coefficient can be determined for each portion.

18. The photomask of claim 17, wherein the line width of each portion is corrected in the x direction by multiplying it width the correction coefficient corresponding to each portion.

19. The photomask of claim 17, wherein the line width of each portion is corrected in the y direction by multiplying it width the correction coefficient corresponding to each portion.
